(19) United States
(12) Patent Application Publication
(10) Pub. No.: US 2007/0182420 A1
(43) Pub. Date: Aug. 9, 2007

(54) Method and system for estimating driving point voltage

(76) Inventor: Paul R. Buda, Raleigh, NC (US)

Correspondence Address: Richard C. Himelhoch;Wallenstein & Wagner, Ltd., 53rd Floor, 311 South Wacker Drive, Chicago, IL, 60606-6630, US

(21) Appl. No.: 11/517,687

(22) Filed: Sep. 8, 2006

Related U.S. Application Data
(60) Provisional application No. 60/727,425, filed on Oct. 17, 2005.

(51) Int. Cl. G01R 31/08

(52) U.S. Cl. 324/522

(57) ABSTRACT

A method and system for estimating a driving point voltage of a resistance weld system. The method includes periodically sampling a supplied voltage and a supplied current of a system to obtain a plurality of sets of a sampled voltage value and a sampled current value. The sampled values are used for creating a volt time area of the sampled voltage, a current time area of the sampled current, and a current difference time area of the sampled current. The method further includes creating an estimated line resistance and an estimated line reactance of the system based on the first set of a sampled voltage value and a sampled current value and the second set of a sampled voltage value and a sampled current value. The volt time area, current time area, current difference time area, line resistance and line impedance are used for creating a driving point voltage area or waveform. The system includes circuitry for implementing the method for a resistance weld control.

### CROSS-REFERENCE TO RELATED APPLICATIONS

The present application claims the benefit of Provisional Application No. 60/727,425 filed Oct. 17, 2005, the contents of which are incorporated herein by reference. The present application is being filed concurrently with U.S. patent application Ser. No. ______ (not yet assigned) entitled “Improved Phase Reference Generator With Driving Point Voltage Estimator” (Attorney Docket No.: SAA-128-1 (402P348)).

### FEDERALLY SPONSORED RESEARCH OR DEVELOPMENT

N/A

### TECHNICAL FIELD

The invention generally relates to a system and method for providing improved thyristor timing in AC phase controllers, and more particularly to a system and method for providing improved timing for resistance welding operations.

### BACKGROUND OF THE INVENTION

A phenomenon that can limit the performance of thyristor or silicon controlled rectifier (SCR) based phase controllers in general, and resistance weld controllers in particular, is the distortion of the observed voltage waveform caused by the presence of line impedance when current flows. In phase controlled resistance welders, precise control of current over a few line cycles is required in order to generate the energy profile required to establish a strong, secure weld. To accomplish this requires that the firing pulses which trigger the SCRs be timed precisely relative to the AC power source applied to it. A modern resistance weld control must therefore maintain an accurate internal time base with respect to the power source. This internal time base is referred to herein as a phase reference generator (PRG).

Traditionally, weld controls maintain an internal time base on which phase locked loop systems employ a phase discriminator based on the zero-crossings of an observed waveform to generate timing information on which an internal time base can be generated. However, this method is inadequate for generating a time base for resistance welding applications because the flow of current into the weld causes distortion in the zero-crossings of the voltage waveform as observed by the weld control at its terminals.

Several attempts have been made to provide improved welding conditions. U.S. Pat. No. 5,856,920 discloses a method of estimating the phase error between two independent time bases. In particular, this patent discloses a method of estimating the phase error between an internally maintained time base (phase reference generator), and an observed sinusoidal voltage. The method of estimating the phase error between the two independent time bases comprises dividing the time base of the internal phase reference generator into “quadrants”, and integrating the volt-time area of the observed absolute value of the sinusoidal voltage over the quadrants. In one implementation, the phase estimator computes the ratio of the difference between the sum of the volt-time area of the first two quadrants and the sum of the last two quadrants, divided by the total sum of all quadrants. In another implementation, the volt-time area of two adjacent quadrants are used to estimate the phase error.

U.S. Pat. No. 5,869,800 discloses the use of a phase distortion compensated time base for a welder control to improve the timing of firing the thyristors in a solid state phase controlled resistance welder control.

U.S. Pat. No. 5,963,022 discloses a method and apparatus for synchronizing an internal time base to an observed line voltage based on observing the voltage, estimating the phase distortion generated by coupling of the AC line voltage source to the load as a result of the load being energized from the phase angle firing control in the presence of line impedance and adjusting the internal phase reference generator in response to the estimated phase distortion. This patent also discloses observing the line voltage waveform under a condition in which the system is not conducting current, freezing the phase reference generator frequency and phase for one or more line cycles in which the system is conducting current to observe the phase error resulting from estimating the phase under conditions of current flow without compensating for the observed phase error, then biasing the phase error in subsequent phase error samples by the observed amount while compensating for the biased phase error. The method described in this patent makes a very noticeable improvement in the performance of a resistance weld control, especially when the intent of the control is to generate a sequence of current pulses of the same current. However, in certain circumstances, particularly those in which the current ramps from an initial value to a final value over a number of line cycles the performance, while better than a system without such compensation, is not as accurate as it could be.

U.S. Pat. No. 6,013,892 discloses a phase controlled weld system that computes a firing sequence based on estimated models of line impedance, open circuit line voltage, and an estimated relation between the load current and conduction angle and the mathematical relation between firing angle, conduction angle and load circuit power. The system also uses measured values received in real time to modify the nominal firing angle. This system is also not as accurate as it could be.

The present invention is provided to solve the problems discussed above and other problems, and to provide advantages and aspects not provided by prior systems of this type. A full discussion of the features and advantages of the present invention is deferred to the following detailed description, which proceeds with reference to the accompanying drawings.

### SUMMARY OF THE INVENTION

The present invention is a method and system for improved timing in AC phase controllers, such as resistance weld controllers. Specifically, the improved method and system can be used with an EQ5400 AC Resistance Weld Control. This weld control is utilized in resistance welding applications, including but not limited to automobile body assembly.

The present invention substantially improves the performance of a resistance weld control's ability to track the driving point voltage (the open circuit voltage that would be observed if no current were flowing) by estimating in real time the driving point voltage waveform under all conditions. There is no longer the need to “freeze” the phase and frequency of the phase reference generator at initiation of a weld. The present system accomplishes this by assuming a simple circuit model for the power source and distribution system providing power to the weld control comprising an ideal, time varying driving point voltage source, a series line resistance and a series line reactance. Using the estimated parametric values of line resistance and line reactance, an estimated driving point volt-time area is computed and used in the conventional manner as the basis for generating a phase reference generator that automatically tracks the power source under all conditions.

According to one embodiment of the invention, the system estimates the driving point voltage magnitude and phase in an AC phase controlled resistance weld application relative to an internal phase reference generator. The system provides improved tracking of the driving point voltage phase while welding. This results in more accurate timing of thyristor firing points and consequently better current accuracy during a resistance welding operation. The system also provides improved run to run load impedance estimates, resulting in more accurate feed-forward control. The system also provides improved line voltage compensation while welding.

In accordance with another embodiment of the invention, a method and system for estimating a driving point voltage of a resistance weld system is provided. The method comprises the steps of periodically sampling a supplied voltage and a supplied current of a system to obtain a plurality of sets of a sampled voltage value and a sampled current value. The sampled voltage and current is utilized for creating a volt-time area of the sampled voltage, a current time area of the sampled current, and a current difference time area of the sampled current. The method further includes determining if current is one of flowing and not flowing, and taking a first set of a sampled voltage value and a sampled current value when the current is not flowing and taking a second set of a sampled voltage value and a sampled current value when the current is flowing. From these two sets of values, the method includes creating an estimated line resistance and an estimated line reactance of the system.

The method further comprises the step of using the volt-time area of the sampled voltage, the current time area of the sampled current, the current difference time area of the sampled current, the estimated line resistance and the estimated line reactance to create an estimated driving point voltage time area. The estimated driving point voltage time area is used to drive the firing of a thyristor of a resistance weld device.

The steps of creating a volt-time area of the sampled voltage, creating a current time area of the sampled current, and creating a current difference time area of the sampled current can be accomplished on a quadrant by quadrant basis. In this instance, the step of periodically sampling a supplied voltage and supplied current of a system comprises sampling the supplied voltage and current a set number of times for each quadrant.

The method can also include various provisions to ensure the estimated phase reference is in phase with the supplied voltage. In this regard, the method includes using the estimated driving point voltage time area to compute a phase error between the supplied voltage and an internal phase reference. The phase error can then be utilized in creating a driving point voltage waveform model in synch with the supplied voltage.

Circuitry in a weld control of the resistance weld system, and components for measuring the supplied voltage and current, are utilized by the system to implement the method steps. The circuitry can include a digital signal processor having firmware and/or software necessary to implement the functions described.

In accordance with another embodiment of the invention, a method for estimating a driving point voltage for timing the firing elements of a resistance weld device comprises measuring a supplied voltage and a supplied current of a power distribution system at a plurality of predetermined intervals, estimating a line resistance and a line reactance based on the measured values of the supplied voltage and the supplied current, and estimating the driving point voltage based on the measured values of supplied voltage and the supplied current, and on the estimated line resistance and line reactance. The estimated driving point voltage is used by a phase reference generator as the timing basis for providing a firing signal to a thyristor of a resistance weld device.

The method can further include calculating a voltage time area of the supplied voltage from the measured values of the supplied voltage, calculating a current time area of the supplied current from the measured values of the supplied current and, calculating a current difference time area of the supplied current from the measured values of the supplied current. The voltage time area, the current time area and the current difference time area are used for estimating the driving point voltage.

The step of estimating a line resistance and a line reactance can comprise measuring a first set of a sampled voltage value and a sampled current value when the current is not flowing, measuring a second set of a sampled voltage value and a sampled current value when the current is flowing and, creating an estimated line resistance and an estimated line reactance of the system based on the first set of a sampled voltage value and a sampled current value and the second set of a sampled voltage value and a sampled current value. The estimated line resistance and line reactance can also be utilized in estimating the driving point voltage.

The method can further include estimating a phase error between the supplied voltage and the estimated driving point voltage. The estimated phase error can be used to determine the difference in phase between an internal time base and the phase of the estimated driving point voltage

In accordance with another aspect of the invention, a method for estimating a driving point voltage of a resistance weld system is provided. The method includes periodically sampling a supplied voltage and a supplied current of a system to obtain sets of a sampled voltage value and a sampled current value. This can include taking a first, second and third set of a sampled voltage value and a sampled current value, and computing a current difference value for each of the first, second and third sets. The method further includes creating an estimated line resistance and an estimated line reactance of the system based on the first set of a sampled voltage value, a sampled current value and computed current difference value, the second set of a sampled voltage value, a sampled current value and computed current difference value, and the third set of a sampled voltage value, a sampled current value and computed current difference value.

The method can also include taking one of the sampled sets when the current is not flowing (i.e., equals zero). This can include the steps of determining if the current is flowing or not flowing, and sampling the voltage when the current is not flowing. Choosing this data set can simplify some of the calculations involved in determining the driving point voltage.

In accordance with a further embodiment of the invention, a phase reference generator for tracking the driving point voltage waveform of a power distribution system for use in a resistance weld control is provided. The phase reference generator comprises a digital signal processor configured to include: a digital volt-time area generator to generate a volt-time area of an observed voltage; a digital current-time area and current-difference-time area generator to generate a current-time area of an observed current and a current-difference-time area of the observed current; a line impedance estimator; and, a driving point voltage area estimator configured to receive values from the digital volt-time area generator, the digital current-time area generator and current-difference-time area generator, and the line impedance estimator and generate estimates of the driving point voltage. The phase reference generator can be used to provide an output signal to fire a resistance welder.

The phase reference generator further comprises an analog to digital converter for converting each of the observed voltage and the observed current from an analog signal to a digital signal. The phase reference generator also includes an interval timer which-triggers an analog to digital conversion of the observed voltage and observed current.

The phase reference generator can also include a phase error estimator. The phase error estimator is configured to estimate the phase difference between the estimated driving point voltage and a timing cycle generated by the phase reference generator. The phase error estimator is implemented in firmware of the digital signal processor once for every timing cycle generated by the phase reference generator.

The phase reference generator further comprises a compensator configured to adjust a frequency of the timing cycle to move the timing cycle toward a synchronous phase with the estimated driving point voltage. To accomplish this, the compensator either increases the frequency of the timing cycle when the timing cycle lags the estimated driving point voltage or decreases the frequency of the timing cycle when the timing cycle leads the estimated driving point voltage.

The phase reference generator can further include a quadrant generator. The quadrant generator is configured to provide an indication of a current quadrant of the timing cycle.

In accordance with another embodiment of the invention, a weld control for a resistance weld system is provided. The weld control comprises a phase reference generator configured to provide an estimated driving point voltage of a supplied voltage and generate a signal for firing a thryristor of the weld system during a welding operation. The weld control also includes a voltmeter function coupled to the phase reference generator and an input line to provide sampled values of the input line voltage and, a current-meter function coupled to the phase reference generator and the input line to provide sampled values of the line current.

The phase reference generator can comprise a digital signal processor. The digital signal processor can include firmware and/or software configured to function as a digital volt-time area generator, a digital current-time area and current-difference-time area generator, a line impedance estimator and a driving point volt-area estimator. The digital volt-time area generator generates an estimate of the input line voltage based on the sampled values of the input line voltage. The digital current-time area and current-difference-time area generator generates an estimate of the line current and the difference of the line current from the sampled values of the line current.

The digital signal processor further includes a line impedance estimator. The line impedance estimator is configured to generate an estimate of the line resistance and line reactance based on measured input line voltage, measured line current and computed first difference of the line current.

The digital signal processor further includes a driving point volt-time area estimator. The driving point volt-time area estimator is configured to provide an estimate of the driving point volt-time area based on the estimate of the input line voltage, the estimate of the line current and the difference of the line current, the line resistance and the line reactance.

The digital signal processor further includes a quadrant generator for providing a phase reference generator timing cycle having a frequency. Additionally, the digital signal processor includes a phase error estimator to estimate the phase error between the driving point voltage estimate and the internal system timing cycle. Based on the estimated phase error, the digital signal processor utilizes a compensator for adjusting the frequency of the timing cycle to bring the timing cycle in synchronization with the driving point voltage.

In accordance with a further embodiment of the invention, a digital phase reference generator for use in a weld control is disclosed. The digital phase reference generator comprises an interval timer configured to trigger an analog to digital conversion of a sampled input line voltage and a sampled input line current on a reoccurring basis. The input line voltage and current are from a power distribution system. The digital phase reference generator further comprises a digital signal processor configured to run an interrupt routine initiated by each completion of the analog to digital conversion of a sampled input line voltage and a sampled input line current wherein a predetermined number of interrupt routines defines a timing cycle, the digital signal processor further configured to generate a volt-time area estimate of the input line voltage, a current-time area estimate of the input line current and a current-difference-time area estimate of the input line current, and a line impedance estimate. The digital signal processor is configured to provide a driving point volt-time area estimate of the input line voltage. The driving point volt-time area estimate is used as the basis for computing the error between the timing of the phase reference generator and the driving point voltage. The phase reference generator is used as the timing basis of for the firing of thyristors of a resistance welding system. Unlike a prior art system in which the phase reference generator timing period is held constant for the first few cycles of welding while the system determines the phase error caused by the distortion of the driving point voltage due to line impedance, a system incorporating the invention disclosed herein can continue to track the driving point voltage even under conditions of rapidly varying weld current.

Other features and advantages of the invention will be apparent from the following specification taken in conjunction with the following drawings.

### BRIEF DESCRIPTION OF THE DRAWINGS

To understand the present invention, it will now be described by way of example, with reference to the accompanying drawings in which:

FIG. 1 is a block diagram of a phase reference generator in accordance with an embodiment of the present invention;

FIG. 2 is a diagram defining the quadrants of a phase reference generator cycle, when the phase reference generator is properly synchronized with the observed line voltage waveform;

FIG. 3 is a block diagram of a phase reference generator compensator control system utilized in the phase reference generator of FIG. 1;

FIG. 4 is a flow chart of a quadrant generator;

FIG. 5 is a block diagram of a digital volt-time area generator utilized in the phase reference generator of FIG. 1;

FIG. 6 is a block diagram of a digital current-time area generator utilized in the phase reference generator of FIG. 1;

FIG. 7 is a block diagram of a driving point volt-time area estimator utilized in the phase reference generator of FIG. 1;

FIG. 8 is a block diagram of a line impedance estimator utilized in the phase reference generator of FIG. 1;

FIG. 9 is a block diagram of a run to run (R2R) autoregressive filter utilized in the line impedance estimator of FIG. 9;

FIG. 10 is a logic flow chart of a line impedance supervisor utilized in the phase reference generator of FIG. 1;

FIG. 11 is a block diagram of a phase error estimator utilized in the phase reference generator of FIG. 1;

FIG. 12 is a state diagram of a phase reference generator state machine

FIG. 13 a table showing phase reference generator settings for a resistance weld control;

FIG. 14 is a quadrant diagram of a phase reference generator cycle showing the relation between the PRG and the input voltage sinusoid where the PRG is synchronized with the input voltage sinusoid;

FIG. 15 is a quadrant diagram of a phase reference generator cycle showing the relation between the PRG and an input voltage sinusoid where the PRG is not synchronized with the input voltage sinusoid;

FIG. 16 is a table of parametric values of a sampled data system;

FIG. 17 is a stem plot showing sample values of the voltage waveform for parametric values in the table of FIG. 16;

FIG. 18 is a circuit diagram of an ideal circuit model for a weld control;

FIG. 19 is a circuit diagram of a system model of a weld control with line impedance;

FIG. 20 is a table of parametric values for the circuit of FIG. 19;

FIG. 21 is waveforms of the source volts, observed volts and weld current showing distortion caused by the presence of line impedance;

FIG. 22 is a lumped parameter circuit diagram of a resistance weld control and associated power distribution system;

FIG. 23 is a line voltage waveform as a function of time and a line voltage waveform as a function of observation angle;

FIG. 24 is a simplified model of a weld circuit assuming no line impedance;

FIG. 25 is a voltage waveform resulting from firing a thyristor with respect to time and a voltage waveform resulting from firing a thyristor with respect to an observed angle;

FIG. 26 is a current waveform resulting from applying the parametric values of the table of FIG. 27 to a weld current equation; and,

FIG. 27 is a table of parametric values for a weld current equation.

### DETAILED DESCRIPTION

While this invention is susceptible of embodiments in many different forms, there is shown in the drawings and will herein be described in detail preferred embodiments of the invention with the understanding that the present disclosure is to be considered as an exemplification of the principles of the invention and is not intended to limit the broad aspect of the invention to the embodiments illustrated.

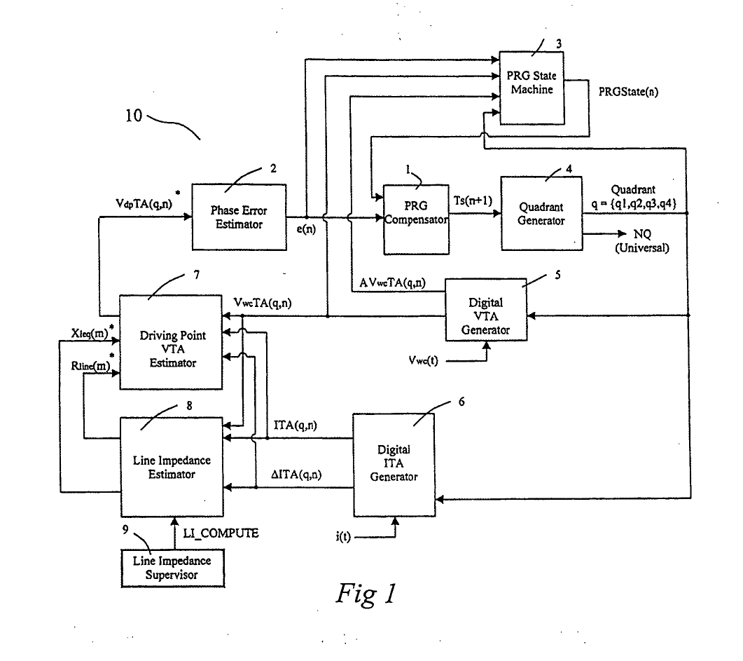

Referring to FIG. 1, a block diagram is disclosed of the components of a phase reference generator (“PRG”) 10 for providing improved tracking of a line voltage to create more accurate firing points of a resistance welding device. The present invention is preferably implemented in connection with a resistance weld control, such as the EQ5400 AC Resistance Weld Control sold by the Square D Company, to create a PRG timing cycle to match the driving point voltage of a power supply and distribution system. The EQ5400 AC Resistance Weld control can be modified to include the features of the present invention as discussed below.

In an embodiment utilizing a EQ5400 AC Resistance Weld Control, a commercially available digital signal processor (DSP), preferably Model TMS320F2407A, manufactured by Texas Instruments, is employed to perform an analog to digital conversion of external voltage and current signals, digital signal processing, and timing generation. In this embodiment, PRG timing is controlled by a hardware interval timer included in the DSP, the interval of which can be set under software control. When the timer period expires, it begins timing a new period, and simultaneously triggers the analog to digital conversion of a sequence of selected signals, independent of the present processing being performed by the DSP. This includes signals responsive to the instantaneous weld current and the voltage observed at the input terminals of the weld control. Completion of analog to digital conversion sequence triggers an interrupt in the DSP, which then suspends it's processing for a time and executes a firmware interrupt routine. In this way, time critical operations can be accomplished in a timely manner and at regular intervals. A feature of the particular DSP employed is that the interval timer is “shadowed”, meaning that when a new period is provided to the interval timer, this new period is applied at the expiration of the present interval.

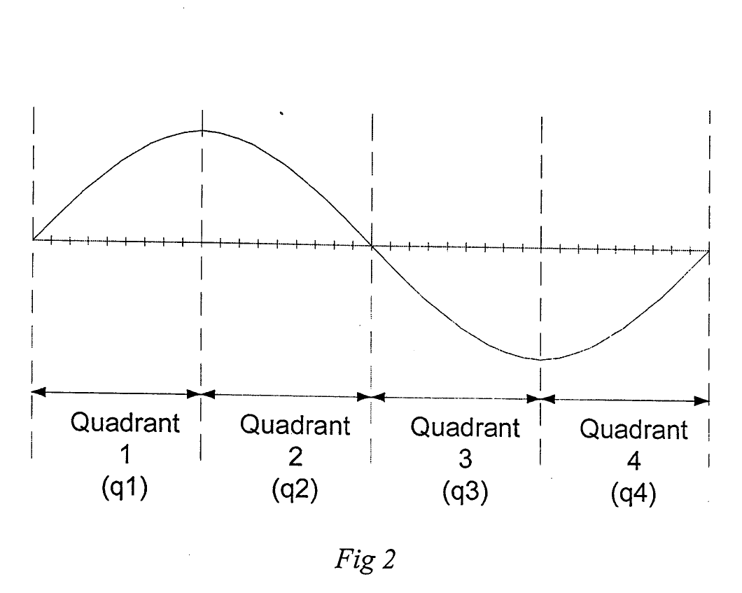

In the EQ5400 AC Resistance Weld Control implementation, the PRG cycle is defined as the interval spanned by 128 interrupts generated by the DSP in accordance with the above description. Each PRG cycle is divided into four quadrants, labeled q1, q2, q3 and q4 in FIG. 2. Each quadrant represents an interval of 32 DSP interrupts. From the above discussion, it is clear that the time period of a PRG cycle is variable, and it is this feature that allows the PRG cycle to synchronize with an observed sinusoidal waveform as shown in FIG. 2 and discussed below. As the system is designed, the interrupt interval is constant within a PRG cycle.

The objective of the PRG 10 is to synchronize the internal quadrants with the observed voltage source such that if the PRG cycle is synchronized with a purely sinusoidal voltage of constant magnitude, the quadrants correspond to the following (shown visually in FIG. 2): Quadrant 1 represents the interval between the negative to positive zero crossing of the sinusoid and the positive peak of the sinusoid; Quadrant 2 represents the interval between the positive peak of the sinusoid and the positive to negative zero crossing of the sinusoid; Quadrant 3 represents the interval between the positive to negative zero crossing of the sinusoid and the negative peak of the sinusoid; and Quadrant 4 represents the interval between the negative peak of the sinusoid and the negative to positive zero crossing of the sinusoid.

FIG. 1 is a top level block diagram showing the closed loop system of the present invention to model, estimate and track the driving point voltage. The various components shown can be implemented in the firmware and/or software of the DSP, and may include additional the use of additional circuitry, and are sometimes referred to herein as functions of the PRG. The index “n”, appearing in various quantities refers to the nth PRG cycle after a reference cycle, normally the first cycle after the system is powered. It should be understood that this index, n, is a mathematical entity, incorporated to make use of difference equations in a standard, mathematical format. The value of the interrupt period, Ts(n+1), for the next PRG cycle is supplied by a PRG Compensator 1. Inputs to the PRG Compensator 1 are the phase error sequence e(n), generated by a Phase Error Estimator 2, and the “state” of the PRG, labeled PRGState(n), generated by a PRG State Machine 3. The PRG Compensator 1 is executed once per PRG cycle, sometime in the interval of quadrant 4 in FIG. 2, when all inputs required to execute the PRG Compensator for the present PRG cycle are available

Interrupt period Ts(n+1), generated by the PRG Compensator 1, is furnished to a Quadrant Generator 4 which is a function resident in DSP firmware. Quadrant Generator 4 is executed once per interrupt. It declares to the system the present quadrant value, q, in the set {q1, q2, q3, q4}. It also furnishes a universal logical semaphore, NQ, indicating the beginning of a new quadrant when set TRUE. The value of this logical semaphore is known universally to all functions in the PRG system. Quadrant Generator 4 also manages the timing of application of the new interrupt period, setting it at the transition between q4 of the present PRG cycle and q1 of the next PRG cycle. The PRG quadrant value q is an input to the PRG State Machine 3, a digital volt-time area generator 5, labeled Digital VTA in FIG. 1, and a digital current-time and current-difference-time generator 6, labeled Digital ITA Generator in FIG. 1.

Digital VTA Generator 5 is executed once per DSP interrupt and generates an estimate of the observed volt-time area, V_{wc}TA(q,n) for each quadrant from the quantized, digitized samples of the continuous analog line voltage waveform V_{wc}(t) generated by the analog to digital converter function of the DSP. Digital VTA Generator 5 also generates an estimate of the observed absolute volt-time area, AV_{wc}TA(q,n) in a manner to be described subsequently.

Digital ITA Generator 6 is also executed once per DSP interrupt and generates quadrant by quadrant current-time estimates ITA(q,n) and estimates of the area of first difference of current, ΔITA(q,n), from the quantized, digitized samples of instantaneous current generated by the analog to digital converter function of the DSP.

Driving Point VTA Estimator function 7 is executed once per quadrant and utilizes the V_{wc}TA(q,n) values furnished by Digital VTA Generator function 5 and the ITA(q,n) and ΔITA(q,n) values furnished by Digital ITA Generator function 6, along with estimated values of line resistance, R*ₗᵢₘₑ(m) and X*_{leq}(m), furnished by a Line Impedance Estimator function 8 to generate quadrant estimates of driving point volt-time area, V_{dp}TA(q,n). The significance of the index “m” in R*ₗᵢₙₑ(m) and X*_{leq}(m) will be discussed subsequently. The quadrant estimates of V_{dp}TA(q,n) are fed to a Phase Error Estimator function 2, executed once per PRG cycle when the driving point volt-time area estimates are available from quadrants 2 and 3. Phase Error Estimator 2 computes an estimate of phase error between the estimated open circuit source voltage waveform and the present timing of the PRG quadrants. The output of Phase Error Estimator 2 is a sequence of phase error values, e(n), one per PRG cycle, which feeds the PRG Compensator 1, closing the loop.

As described above, the estimated sequences of line resistance, R*line(m) and reactance, X*_{leq}(m) are furnished by Line Impedance Estimator function 8. This Line Impedance Estimator function utilizes the outputs furnished by Digital VTA function 5 and Digital ITA function 6, along with an external knowledge of when to compute a new line impedance estimate furnished by a Line Impedance Supervisor function 9 to be described subsequently.

In the block diagram of FIG. 1, the Line Impedance Supervisor function 9 furnishes a software semaphore command, LI_COMPUTE to Line Impedance Estimator function 8 to determine on which PRG cycles to compute a new estimate of line impedance parameters R*ₗᵢₙₑ(m) and X*_{leq}(m). The index “m” in the line impedance parameter values refers to the mth such update of line impedance parameters from initialization of the system since power was first applied.

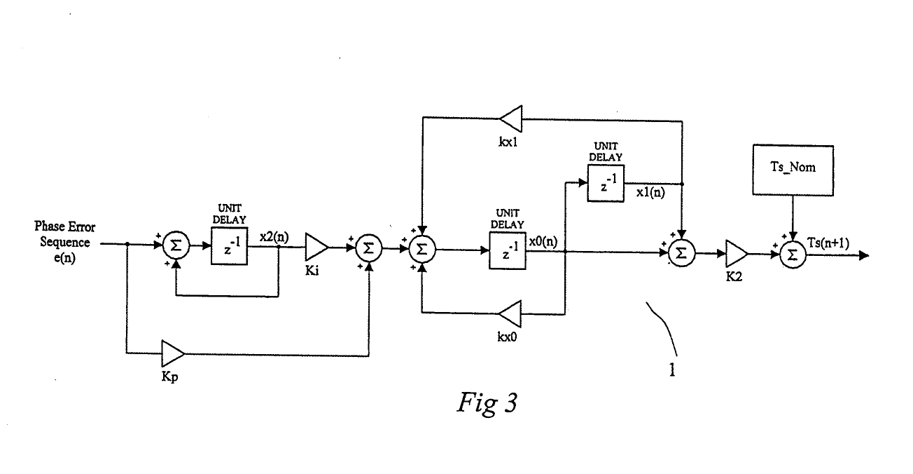

FIG. 3 shows a system block diagram description of the PRG Compensator function 1 of FIG. 1. In the EQ5400 AC Resistance Weld Control, this function is implemented totally in DSP firmware. PRG Compensator function 1 is executed once per PRG cycle, at a time when the most recent phase error estimate, e(n) is available, after quadrant q3, and in time for Quadrant Generator 4 to set the elementary sample rate for the next PRG line cycle., Ts(n+1).

PRG Compensator 1 attempts to drive the estimated phase error between the PRG timing cycle and the estimated driving point voltage signal by slightly increasing the internal PRG frequency to “catch up” with the estimated driving point voltage signal if the PRG timing cycle phase lags the estimated driving point voltage signal, or decreasing the internal PRG frequency to allow the estimated driving point voltage signal to “catch up” with the PRG timing if the estimated phase error shows the PRG timing cycle leads the external driving point voltage signal.

Mathematically, there are three internal state variables maintained by PRG Compensator function 1, labeled x0(n), x1(n) and x2(n) in FIG. 3. State variable x2(n) represents the accumulated sum of the phase error since the PRG Compensator 1 has been initialized in a manner to be described subsequently. The state variables x0(n) and x(n) are incorporated to permit the response of the system to be completely controlled, accommodating for the fact that the phase error is estimated at a point that is at the center of a present PRG cycle, whereas the consequent adjustment in timing is made at the quadrant transition between q4 of the present cycle and q1 of the next cycle. Using well understood techniques of modern linear control theory, it can be shown that when coupled in to the system, such a system is completely controllable in a control system sense, and that the response of the system can be set to any reasonable value desired.

In matrix format, the form of the state difference equations describing PRG Compensator function 1 are:

$$[ \begin{matrix}x 0 ( n + 1 ) \\ x 1 ( n + 1 ) \\ x 2 ( n + 1 )\end{matrix} ] = [ \begin{matrix}kx 0 & kx 1 & ki \\ 1 & 0 & 0 \\ 0 & 0 & 1\end{matrix} ] [ \begin{matrix}x 0 ( n ) \\ x 1 ( n ) \\ x 2 ( n )\end{matrix} ] + [ \begin{matrix}kp \\ 0 \\ 1\end{matrix} ] e ( n ) \qquad ( 1 )$$

with the output Ts(n+1) given by:

$$Ts ( n + 1 ) = {Ts}_{nom} + [ \begin{matrix}K 2 & K 2 & 0\end{matrix} ] [ \begin{matrix}x 0 ( n ) \\ x 1 ( n ) \\ x 2 ( n )\end{matrix} ] \qquad ( 2 )$$

where kx0, kx1, ki, kp, and K2 are control system parameters, and the value Tsₙₒₘ represents the expected elementary sample period. The specific values of these constants are dependent upon the state of PRG Generator 10, furnished by PRG State Machine 3 in the state variable PRGState(n+1). Discussion of the actual parametric values used as a function of the system state is deferred to the description of the PRG State Machine.

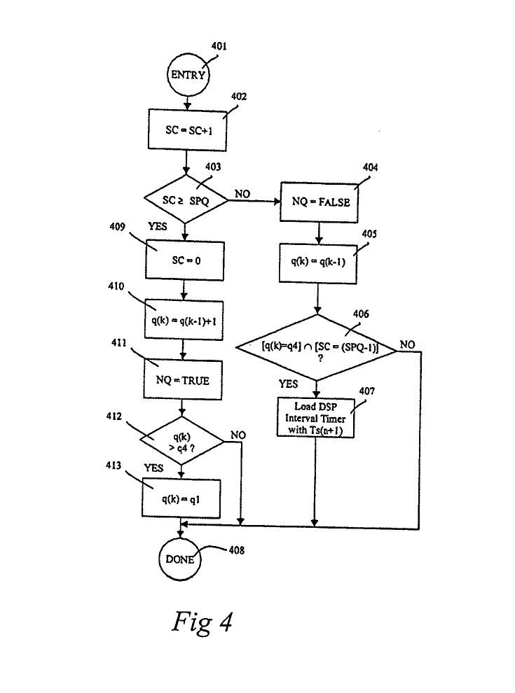

Quadrant Generator 4 is also implemented in DSP firmware and is executed on each DSP interrupt of the system. FIG. 4 is a flowchart showing the process of the Quadrant Generator 4. The Quadrant Generator 4 maintains an internal counter, SC, of DSP interrupts from the beginning of the present PRG quadrant. Upon entry at 401 on the kth DSP interrupt since the beginning of the present PRG quadrant, Quadrant Generator 4 first increments the value of the SC counter in process block 402. In decision block 403, the DSP compares the value of the counter SC to a constant value SPQ, indicating the number of DSP interrupts per quadrant. In the implementation of the EQ5400 AC Resistance Weld Control, SPQ is 32. If the value of SC is not greater than or equal to SPQ, control passes to control block 404, in which the new quadrant semaphore, NQ is set FALSE, indicating that this elementary sample does not represent the beginning of a new quadrant. The value of this semaphore is known universally to the system. Once the NQ semaphore has been set FALSE in 404, the system sets the present quadrant value, q(k) to the previous value, q(k-1) in process block 405, since the quadrant has not changed.

In decision block 406, the Quadrant Generator 4 looks for the specific condition of the last DSP interrupt in quadrant q4. This condition is indicated by both of the following conditions true:
q(k)=q4 (3)
and
SC=SPQ−1 (4)

If either of these conditions is FALSE, the routine exits normally at 408. If both of these conditions are true, the Quadrant Generator 4 first loads the hardware interval counter of the DSP with the value Ts(n+1) obtained from PRG Compensator 1. This occurs in process block 407, prior to exiting normally at 408. As discussed previously, this new setpoint value will be loaded to set the DSP interrupt period the next time the interval counter reaches it's setpoint value, which is the correct instant to set the DSP interrupt period for the next PRG cycle.

Referring back to decision block 403, if the sample count SC is greater than or equal to the constant value SPQ, it is time to transition to a new quadrant and process blocks 409, 410 and 411 are executed sequentially. In process block 409, the counter SC is reset to zero. In process block 410, the value of the quadrant, q(k) is incremented. In process block 411, the value of the new quadrant semaphore, NQ is set TRUE, indicating to the rest of the PRG functions that this DSP interrupt represents the first DSP interrupt of a new quadrant.

Control then passes to decision block 412 in which the quadrant value q(k), incremented in process block 410 is compared to determine if the new quadrant value falls within the range {q1, q2, q3, q4}. If so, the routine exits normally at 408. If not, the quadrant value q(k) is set to q1, indicating the beginning of a new PRG cycle. Control then exits normally at 408.

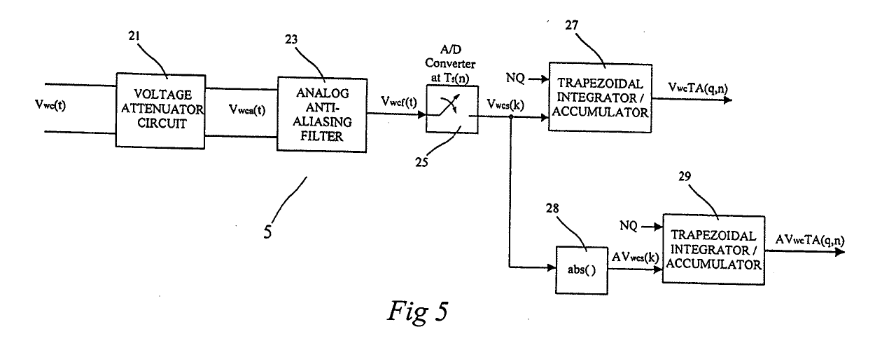

FIG. 5 is a block diagram of the Digital VTA Generator 5. The Digital VTA Generator 5 generates volt-time area estimates of the line voltage at the observed line input of the weld control for each quadrant qε{q1, q2, q3, q4} of the PRG, labeled V_{wc}TA(q,n) in FIG. 1, as well as a quantity AV_{wc}TA(q,n) for each quadrant, formed by first taking the absolute value of the observed weld voltage and generating a trapezoidal accumulation. In the EQ5400 AC Resistance Weld Control, the Digital VTA Generator function is implemented in a combination of analog electronic circuits, digital electronic circuits and digital signal processing firmware. The raw analog voltage line voltage input signal, V_{wc}(t), is that signal appearing at the power input of the weld control. This is a power line voltage signal, typically with a nominal value of 480 Volts RMS in an automobile body shop in the United States. The power system is also capable of supplying very large currents to anything connected to it. Accordingly, to both reduce the voltage observed by the system to the levels that low voltage digital and analog electronics can manage while simultaneously limiting the potential current that can flow into the digital VTA function to safe levels, a voltage attenuator circuit 21 is incorporated in the design. In the EQ5400 AC Resistance Weld Control, the voltage attenuator circuit comprises two commercially available precision high-voltage voltage divider networks, based on thick film technology. The output of the voltage attenuator circuit 21 is a signal V_{wca}(t), responsive to V_{wc}(t), but attenuated by a factor of approximately 125:1, so that a sinusoidal voltage signal of 480 V RMS at the input appears as a sinusoidal signal of about 3.84 V RMS at the output of the attenuator.

The analog signal V_{wca}(t) feeds an anti-aliasing filter 23, which serves to band limit the signal that is fed to AID converter function 25. It is well understood in the study of sampled data systems that to faithfully represent an analog signal as a sequence of digital samples, the sampled signal must be band limited to no more than half the sampling frequency, or the phenomenon commonly called aliasing will result, confounding the result. In the EQ5400 AC Resistance Weld Control, a six pole elliptical filter is implemented in analog hardware to band limit the sampled signal. The attenuated, band limited representation of the line voltage signal is labeled V_{wcf}(t) in FIG. 5.

Analog to digital converter function 25 is integral to the DSP, and samples the signal V_{wcf}(t), responsive to V_{wc}(t) once per DSP interrupt. The sample period for a given PRG cycle is Ts(n), computed by PRG Compensator 1 and set by Quadrant Generator 4. The analog to digital converter quantizes each sample into a 10 bit number in a form that can be used by the DSP. This numeric sequence is labeled V_{wcs}(k) in FIG. 5. In the EQ5400 AC Resistance Weld Control, 128 such samples are taken per PRG cycle.

The sampled and quantized sequence V_{wcs}(k) generated by the A/D converter function of the DSP feeds a functional block labeled trapezoidal integrator/accumulator 27 in FIG. 5. This function is implemented in DSP firmware and estimates the volt-time area of each quadrant by accumulating samples over the quadrant using the trapezoidal integration rule:

$${V}_{wc} TA ( q , n ) = {\sum }_{j = \frac{( q - 1 ) {N}_{s}}{4} + 1}^{\frac{{qN}_{s}}{4}} \frac{{V}_{wcs} ( j ) + {V}_{wcs} ( j )}{2} \qquad ( 5 )$$

where the index j refers to the elementary samples V_{wcs}(k), but referenced to the beginning of the nth PRG cycle. This function creates four such estimates per PRG cycle. Previous quadrant estimates are complete and a new estimate begun upon receipt of the universal new quadrant semaphore NQ from Quadrant Generator 4. To generate the sequence AV_{wc}TA(q,n), supplied by the digital VTA function and used by PRG state machine 3, the mathematical absolute value of the sequence V_{wcs}TA(k) is first taken (shown by reference no.: 28). The output of this absolute value function, labeled AV_{wcs}TA(k) feeds another trapezoidal integrator 29 operating in a manner identical to that which generates the sequence V_{wcs}TA(k). The output of trapezoidal integrator 29 is the sequence AV_{wc}TA(q,n), shown in FIG. 1.

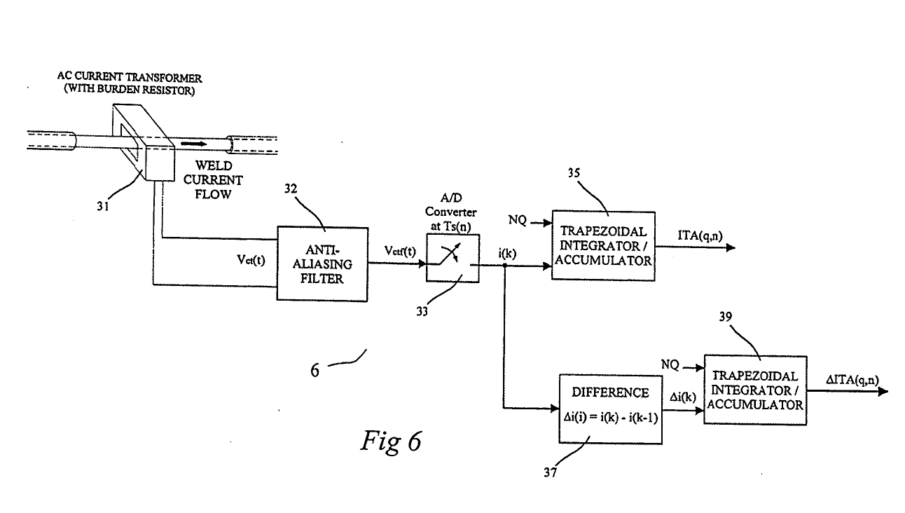

FIG. 6 shows a block diagram of Digital ITA Generator function 6 of the PRG system 10, to estimate the current-time area (ITA) and current time-difference area (ΔITA) of each PRG quadrant. As was the case with the Digital VTA Generator function 5, this function is implemented in a combination of electronic hardware and DSP firmware. In the EQ5400 AC Resistance Weld Control, weld current is passed through a commercially available passive AC current transformer 31 with an associated burden resistor. The current transformer 31 generates a secondary current proportional to the main weld current passing through it's aperture. When this current passes through the burden resistor attached across the transformer secondary, a voltage V_{ct}(t) is generated. As in the Digital VTA Generator function, the voltage V_{ct}(t) is filtered by an analog 6 pole elliptical anti-aliasing filter 32. The resulting band-limited signal is labeled V_{ctf}(t) in FIG. 6.

The band-limited signal V_{ctf}(t), responsive to the instantaneous weld current, is sampled by the DSP analog to digital converter 33, which is a separate analog to digital channel from that of the Digital VTA Generator function 5, but which operates in an identical manner and is sampled essentially at the same instant as that of Digital VTA Generator function 5, at the rate Ts(n) established by PRG compensator 1 and Quadrant Generator 4. The sequence of numbers resulting from this sampling and quantization process is labeled i(k) in FIG. 6.

The sequence i(k) directly feeds trapezoidal integrator/accumulator 35, which operates in a manner identical to that described in the Digital VTA Generator function 5, producing quadrant estimates of current-time area ITA(q,n), with qε{q1, q2, q3, q4}, one per PRG quadrant. The sequence i(k) also feeds a current difference function 37, which generates the sequence Δi(k), according to:
Δi(k)=i(k)−i(k−1) (6)

This signal is fed to another trapezoidal integrator/accumulator 39, which also operates in a manner identical to that described in the Digital VTA Generator function 5, producing quadrant estimates of current-difference-time area, ΔITA(q,n) with qε{q1, q2, q3, q4}, one per PRG cycle quadrant.

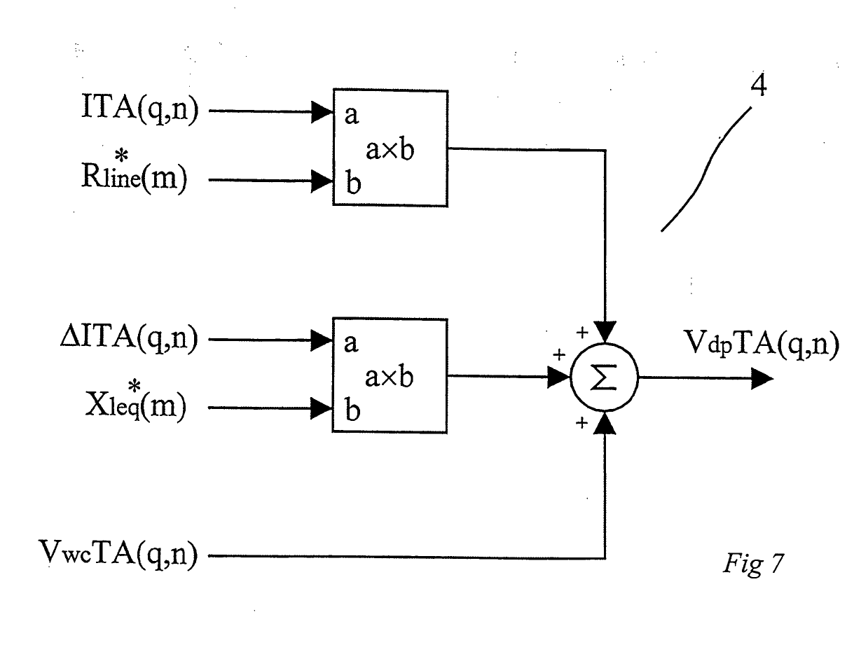

FIG. 7 is a block diagram description of the operation of Driving Point VTA Estimator function 7. This function is executed once per quadrant on the transition of one quadrant to another to produce quadrant open circuit VTA estimates V_{dp}TA(q,n) used by Phase Error Estimator 2. Once all of the data is available, the system executes the mathematics of FIG. 7, which implements the equation:
V_{dp}TA(q,n)=V_{wc}TA(q,n)+[R*ₗᵢₙₑ(m)×ITA(q,n)]+[X*_{leq}(m)×ΔITA(q,n)] (7)

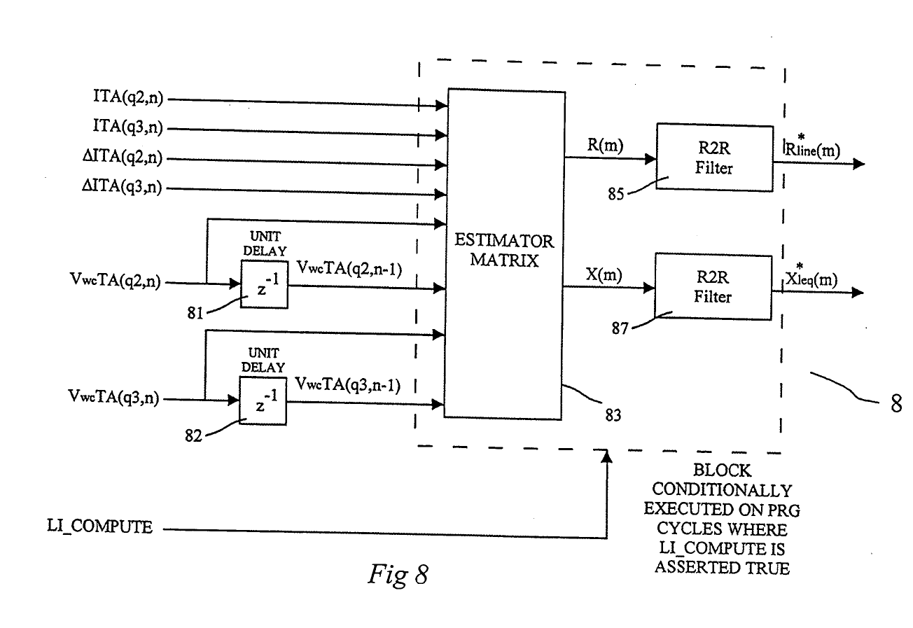

FIG. 8 is a block diagram of the Line Impedance Estimator function 8, which furnishes the line impedance estimates R*ₗᵢₙₑ(m) and X*_{leq}(m) to Driving Point VTA Estimator 7. Line Impedance Estimator function 8 is executed conditionally at certain times, to update the estimates of line resistance and reactance. The command to perform an update is represented by the logical assertion of a signal LI_COMPUTE, which is asserted at times to be discussed subsequently by Line Impedance Supervisor function 9. The index m in the values R*ₗᵢₙₑ(m) and X*_{leq}(m) refers to the mth such commanded update of line impedance values.

In the implementation of the EQ5400 AC Resistance Weld Control, Line Impedance Estimator 8 continuously maintains a memory of the previous value of the observed VTA estimates for quadrants 2 and 3. These signals are represented in FIG. 8 as the outputs of unit delay blocks 81 and 82, and are labeled V_{wc}TA(q2,n−1) and V_{wc}TA(q3,n−1) respectively. Upon command, Line Impedance Estimator 8 generates a new estimate of the line impedance values R*ₗᵢₙₑ(m) and X*_{leq}(m), as determined by assertion of the LI_COMPUTE signal. On this nth line cycle, when the LI_COMPUTE signal is asserted the values ITA(q2,n), ITA(q3,n), ΔITA(q2,n) and ΔITA(q3,n), all furnished by Digital ITA Generator 6, as well as the values V_{wc}TA(q2,n) and V_{wc}TA(q3,n), furnished by Digital VTA Generator 5, and the delayed volt-time area values V_{wc}TA(q2,n−1) and V_{wc}TA(q3,n−1) described above feed estimator matrix 83. Estimator matrix 83 produces outputs R(m) and X(m) according to the equation:

$$[ \begin{matrix}R ( m ) \\ X ( m )\end{matrix} ] = {[ \begin{matrix}ITA ( q 2 , n ) & Δ ITA ( q 2 , n ) \\ ITA ( q 3 , n ) & Δ ITA ( q 3 , n )\end{matrix} ]}^{- 1} [ \begin{matrix}{V}_{wc} TA ( q 2 , n - 1 ) - {V}_{ wc} TA ( q 2 , n ) \\ {V}_{wc} TA ( q 3 , n - 1 ) - {V}_{ wc} TA ( q 3 , n )\end{matrix} ] \qquad ( 8 )$$

where R(m) and X(m) are the instantaneous estimates of resistance and inductive reactance respectively for the mth estimate. The mathematics behind this matrix equation will be derived subsequently.

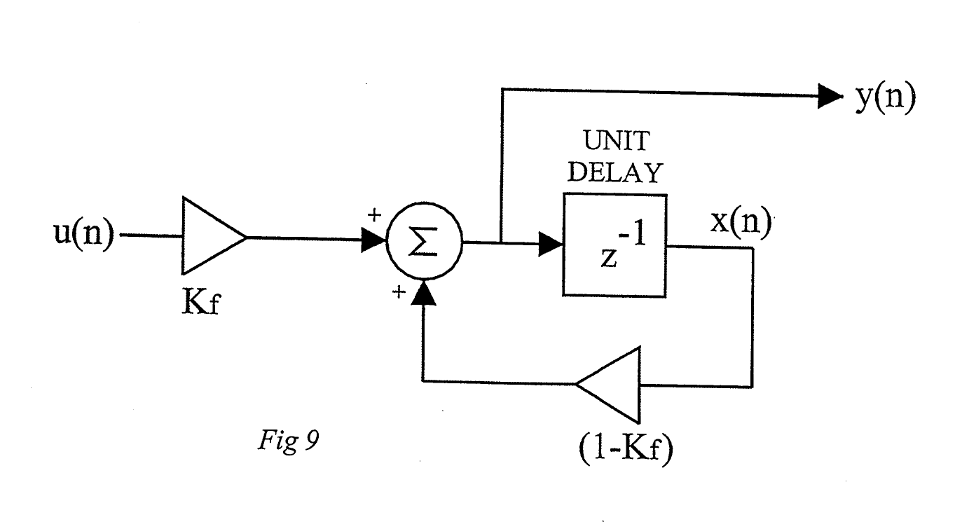

Assumptions made in computing the line impedance estimate are 1) there is one and only one device loading the weld bus at a time and 2) the driving point voltage is a sinusoid and remains constant over the interval on which the computation is based. However, it is recognized that an individual weld control has no knowledge a-priori of the presence or activity of other devices which may be drawing current from the weld power bus, and the instantaneous estimate made using equation (8) above may be in error if other equipment is loading the weld bus over the line cycles in which the estimate is made, violating one or both of the above assumptions To help alleviate this condition, each of the values R(m) and X(m) are filtered utilizing run to run (R2R) filters 85 and 87. A block diagram of the form of these identical filters is shown in FIG. 9. The filters are auto-regressive filters having the general form:
x(m+1)=(1−K_{f})x(m)+K_{f}u(m), 0≦K_{f}≦1
y(m)=x(m+1) (9)
where u(m) is the input to the filter (R(m) or X(m) in FIG. 8), x(m) is the internal state variable, Kf the filter constant, 0≦K_{f}≦1, and y(m) is the output of the filter, Rₗᵢₙₑ(m)* or X_{eq}(m)* respectively in FIG. 8.

The run to run filters tend to “smooth out” the errors that might be made in individual impedance estimates, and result in a more consistent estimate than that which would result from using the individual estimates R(m) and X(m). In practice, using the unfiltered individual estimates R(m) and X(m) directly (which can be done by setting K_{f}=1) has yielded excellent results—the run to run filters are not necessary for the invention to work and should not be considered a limitation on the invention. However, for operation in a noisy environment such as an automobile body shop, it has been found experimentally that inclusion of these run to run filters with K_{f}=0.25 provides an added measure of noise immunity against the condition in which the assumptions above have been violated.

The function of Line Impedance Supervisor function 9, is to determine on which cycles of the PRG to execute Line Impedance Estimator function 8. In the present embodiment, the objective is to execute Line Impedance Estimator 8 on the first cycle in which current is flowing, following several cycles in which current has not been flowing. In a typical automotive application, a resistance weld control is normally idle for several seconds, while a part or an entire automobile is moved into position to be welded. During this period, where no current is flowing, the PRG 10 can acquire the undistorted, driving point voltage waveform of the power system. If it is assumed that the voltage waveform of the power source does not vary much from one cycle to another, then it can be assumed that the voltage waveform on the last line cycle before welding is representative of the driving point voltage waveform of the power source on the first cycle in which welding has begun. The function of Line Impedance Supervisor function 9 is to monitor the system for this condition and trigger execution of Line Impedance Estimator function 8 when the appropriate condition is detected.

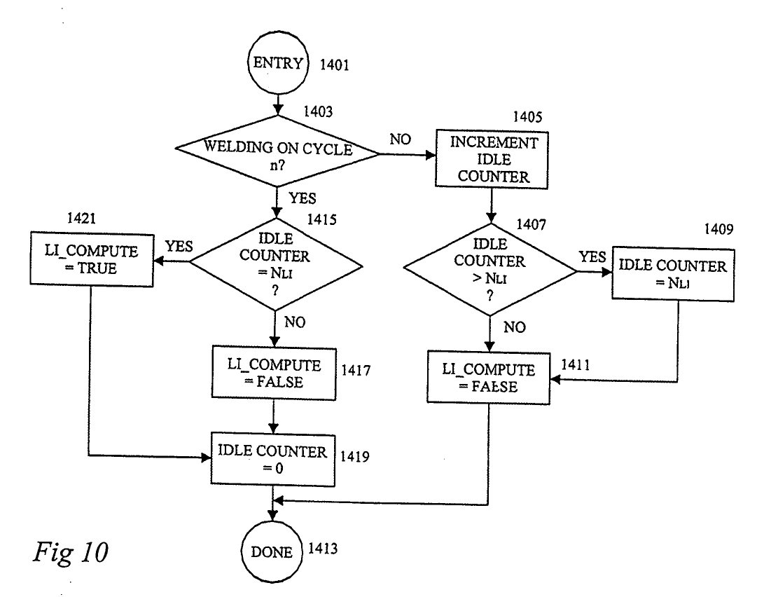

FIG. 10 is a flowchart of Line Impedance Supervisor function 9, which is a DSP firmware entity executed once per PRG cycle. Integral to Line Impedance Supervisor function 9 is a static IDLE counter, used by Line Impedance Supervisor function 9 to determine when the system has been idle for a sufficient period to ensure the PRG is solidly tracking the power source voltage waveform. Referring to FIG. 10, upon entry into the firmware logic at 1401 during line cycle n, the Line Impedance Supervisor function 9 first determines in decision block 1403 whether the system is welding during line cycle n. Assuming the system is not welding during line cycle n, flow is transferred to process block 1405, where an integral IDLE counter is incremented by the DSP. Once the counter is incremented, in decision block 1407 the resulting count is compared against an integer number N_{LI} which is a design parameter indicating the minimum number of non-welding cycles required to ensure the PRG is accurately tracking the power source voltage. If the value in the idle counter is greater than N_{LI}, then the prerequisite number of non-welding cycles has been satisfied and the value in the count is set to N_{LI} in process block 1409. Flow transfers to process block 1411 in which the LI_COMPUTE semaphore is set to a logic FALSE value, indicating to the line impedance estimator 7 that no update of line impedance should be performed.

If in decision block 1407 Line Impedance Supervisor function 9 determines that the value in the IDLE counter is less than or equal to N_{LI}, control transfers directly to process block 1411 and the LI_COMPUTE semaphore is set to a logic FALSE value as above. Once process block 1411 is executed, the routine exits at 1413 until it is again executed at the next PRG cycle.

Referring back to decision block 1403, if it is determined that weld current is flowing on weld cycle n, control passes to decision block 1415, in which the value in the IDLE counter is compared against the value N_{LI}. If it is determined that the value in the IDLE counter is not exactly N_{LI}, then an insufficient number of non-weld cycles were detected to warrant a new estimate of line impedance. This condition exists when a pause between individual welds of less than N_{LI} line cycles occurred, or simply because the system is presently in the middle of executing a weld. In either case, if an insufficient number of non-weld cycles is detected by the routine, the LI_COMPUTE semaphore is set to a logic FALSE state in process block 1417, and the IDLE counter value is set to zero in process block 1419.

If, in decision block 1415, the IDLE counter value is equal to N_{LI}, then the conditions to execute and update of the line impedance estimate are satisfied. Control passes to process block 1421, in which the LI_COMPUTE semaphore is set TRUE. Once this has occurred, control passes to process block 1419 where the IDLE counter value is set to zero as above. Once process block 1419 is executed, the routine exits as above at 1413 until it is again executed at the next PRG cycle.

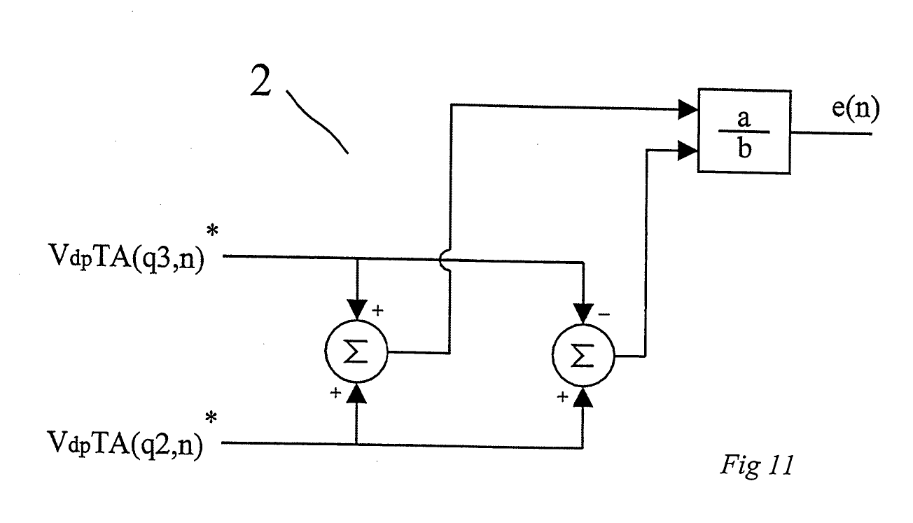

FIG. 11 is an expanded block diagram description of Phase Error Estimator 2 of the PRG system. This function is implemented in DSP firmware, and is executed once per PRG cycle, during quadrant q4, after the driving point voltage estimates V_{dp}TA(q2,n) and V_{dp}TA(q3,n) from quadrants 2 and 3 have been made by Driving Point Voltage Estimator 7. For each line cycle, n, this block utilizes the open circuit volt-time estimates from quadrants 2 and 3, V_{dp}TA(q2,n) and V_{dp}TA(q3,n), furnished by Driving Point Voltage Estimator 7 to estimate the error between the internal time base (i.e., PRG timing cycle) and estimated driving point voltage. The block diagram in FIG. 11 implements the mathematical expression:

$$e ( n ) = \frac{{V}_{dp} TA ( q 2 , n ) + {V}_{dp} TA ( q 3 , n )}{{V}_{dp} TA ( q 2 , n ) - {V}_{dp} TA ( q 3 , n )} \qquad ( 10 )$$

How this expression approximates the error will be-discussed subsequently.

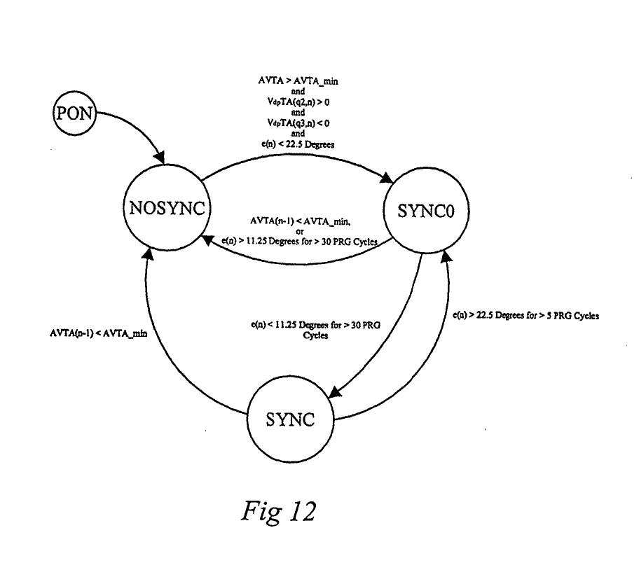

PRG State Machine 3 determines the state of the PRG, and guides the PRG through the process of initialization, when nothing is known regarding the relation between the PRG timing and the actual power system timing, to the point where the PRG is declared “synchronized” with the power system and welding can begin. FIG. 12 shows a system state diagram of PRG State Machine 3. The output of PRG State Machine 3 is the PRG state variable PRGState(n), which takes a value in the set {NOSYNC, SYNCING,SYNC}.

PRG State Machine 3 is implemented in DSP firmware and is executed when the PRG is in quadrant q4, after Phase Error Estimator 2 has been executed for the present PRG cycle. From the power-on state, labeled PON in FIG. 12, the system state is immediately set to NOSYNC. When the system is in the NOSYNC state, nothing is assumed regarding the relation between the PRG quadrants and the observed line voltage waveform. The objective of the PRG 10 in the NOSYNC state is to observe the line voltage V_{wc}(t) and align the PRG quadrants such that the positive to negative zero crossing of V_{wc}(t) occurs near the transition from quadrant q2 to quadrant q3. That this condition exists is determined by satisfaction of the following three conditions:

Condition 1: The sum of the quadrant absolute volt-time areas from the previous line cycle, AV_{wc}TA(q,n−1), q=1,2,3,4, henceforth referred to as AVTA(n−1) is greater than a minimum value. This condition is required to ensure that the system is indeed tracking an actual voltage delivered by the power system of a minimum value, and not just random noise as a result of an open circuit condition in the power system. In the actual design of the EQ5400 AC Resistance Weld Control, the minimum AVTA required to satisfy this condition is the theoretical value that would be obtained by applying a sinusoidal voltage input of 30 Volts RMS, when the line voltage is properly synchronized with the PRG (however, other voltages may be used).

Condition 2: The value V_{dp}TA(q2,n) is positive, and the value V_{dp}TA(q3,n) is negative. This indicates that the zero crossing of the power waveform to be “tracked” occurs somewhere between the present quadrants q2 and q3.

Condition 3: The error value computed by the phase error estimator, e(n) is “small enough” to allow the PRG to begin closed loop acquisition. In the EQ5400 AC Resistance Weld Control, this value is approximately 22.5 degrees.

When in the NOSYNC state, the EQ5400 AC Resistance Weld Control is not allowed to conduct current. One intended consequence of this is that the driving point voltage is identical to that observed by the system at the input terminals of the EQ5400 AC Resistance Weld Control. To accomplish nominal alignment between the PRG 10 and the input sinusoid, the PRG Compensator constants kx0, kx1, ki, kp and K2, shown in FIG. 3 are set to zero and the values of state variables x0(n), x1(n) and x2(n) forced and maintained at zero when the system is in the NOSYNC state, so the PRG 10 does not modify the interrupt sampling period from a nominal value TSₙₒₘ. This results in a fixed PRG cycle frequency while in the NOSYNC mode.

The nominal, operating line frequency voltage of the weld control system is assumed known a-priori. For instance, it is known that a system intended to operate in North America operates at a nominal line frequency of 60 Hz., and that frequency will be quite accurately regulated by the power utility generating the power—generally well within +/−0.2 Hz. When in the NOSYNC mode, the EQ5400 AC Resistance Weld Control utilizes a value of TSₙₒₘ that will generate a PRG frequency 1 Hz. less than the expected operating frequency. For example, for a system intended to operate at 60 Hz, TSn,m is set to 132 microseconds, which results in a PRG cycle frequency of approximately 59 Hz. Accordingly, for a condition in which the positive to negative zero crossing of the actual, observed line voltage occurs outside of quadrants q2 or q3, on each subsequent PRG cycle the zero crossing of the line voltage will occur earlier in the PRG cycle than on the previous PRG cycle, and will occasionally “wrap around” to the next PRG cycle. Eventually, the zero crossing will occur near the transition between q2 and q3 of the PRG. For the given conditions, assuming the line frequency is the nominal value, the estimated phase error should change by only 6 degrees per PRG cycle, ensuring that if condition 1 can be achieved and assuming that the observed waveform is actually sinusoidal in nature, the remaining conditions can be satisfied within ⅓ second under normal conditions. For a system operating nominally at 50 Hz, TSₙₒₘ is selected such that the nominal PRG cycle frequency is approximately 49 Hz.

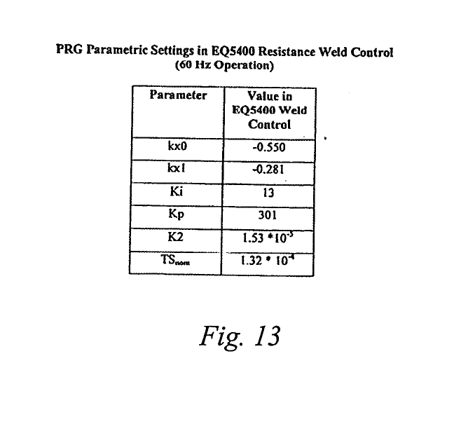

Once the above conditions have been satisfied, the PRG state machine declares the PRG to be in the SYNCO state. In this state, the value of TSₙₒₘ remains fixed at the NOSYNC setting, but the constant kx0, kx1, ki, kp, and K2 are set to their operating values. The table in FIG. 13 provides the parametric values of the PRG compensator 1 presently used in the EQ5400 AC Resistance Weld Control for 60 Hz operation.

The values of state variables x0(n), x1(n) and x2(n), shown in FIG. 3 are explicitly initialized to zero, when the SYNCO state is first entered. Unlike the NOSYNC state, however, they are not maintained at zero, but are allowed to assume values in accordance with the operation of the PRG Compensator 1 previously discussed.

When operated in a closed loop manner in accordance with the PRG system 10 described herein, the parametric values chosen provide excellent system response with good disturbance rejection, driving the estimated phase error sequence, e(n), toward zero in response to reasonable power system line voltages, and establishing the relation between the PRG and the observed power voltage waveform desired in FIG. 2.

Once the PRG constant values have been established, and state variables initialized to zero, the PRG 10 is allowed to operate in the SYNCO state, computing corrections to the interrupt period, Ts(n+1) until one of three events occur:

(1) The observed error, e(n) is below a fixed threshold value for more than a fixed number of consecutive PRG cycles. (2) The observed error, e(n) is greater than the fixed threshold value for greater than a fixed number of consecutive PRG cycles. In the EQ5400 AC Resistance Weld Control, this fixed number is 30 for both cases above. (3) The observed total AVTA for the previous line cycle is less than the minimum value given in the description of the NOSYNC state above.

In the EQ5400 AC Resistance Weld Control, the established error threshold for the SYNCO state is approximately 11.25 degrees. If condition 1 is satisfied first, the PRG transitions to the SYNC state. If either condition 2 or 3 is satisfied first, the PRG transitions back to the NOSYNC state. It is noted that under “normal” operating circumstances, requiring that the error threshold condition be satisfied for 30 consecutive cycles establishes a very small phase error by the time the transition to “SYNC” is made. For a system operating at 60 Hz., this corresponds to ½ second of stable operation under normal conditions.

Upon transition from the SYNCO to the SYNC state, the values of the state variables x0(n), x1(n) and x2(n) shown in FIG. 3 are initialized to zero, and the value TSₙₒₘ is set to TS(n), the last generated interrupt period value from the SYNCO state. Under normal conditions, this new value of TSₙₒₘ generates a PRG cycle period very close to that of the line voltage, so the system now need only make minor corrections to the interrupt sample period for the PRG to maintain synchronization with the line voltage.

In the SYNC state, the EQ5400 AC Resistance Weld Control is permitted to weld. Once in the SYNC state, the PRG remains in that state until one of two conditions occur:

Condition 1: The magnitude of the error estimate, e(n), exceeds approximately 22 degrees for greater than 5 consecutive PRG cycles, in which case the system transitions back to the SYNCO state. This allows the PRG to ride through any minor disturbance that may occur in the power system, while disabling welding and attempting to re-acquire synchronization with the line voltage if the disturbance is large.

Condition 2: The observed total AVTA over the previous line cycle is less than the minimum AVTA described in the NOSYNC state discussion above. If this occurs, the PRG drops immediately back to the NOSYNC state and the system is initialized and operates per the description of the NOSYNC state above.

The Phase Reference Generator 10 in the weld timer provides the timing basis for firing of the thyristors. It also drives the timing of the RMS voltage estimator function (digital voltmeter), as well as the RMS current estimator function (digital current meter). The method of phase error estimation is based on integrating portions of the observed input line voltage to the system.

The following discussion explores the mathematics that is useful in understanding the operation of the present invention in an AC resistance welding application.

In a mathematical circuit model of the power distribution system, it is assumed that the voltage generated by the power generation and distribution system can be modeled as an ideal driving point voltage source V_{dp}(t) of the form:
V_{dp}(t)=Vₘ(t)sin(2πft+φ) (11)
where f is the frequency, φ is the phase of the sinusoid relative to a reference time t=0, Vₘ(t) is the peak voltage, denoted as a function of time. At this point in the discussion, it is recognized that Vₘ(t) is a time varying modulation term. Assumptions on the behavior of Vₘ(t) will subsequently be made that will simplify the analysis.

The objective of the Phase Reference Generator 10 of the present invention is to generate an internal time base that can continuously track the driving point voltage V_{dp}(t) such that the following two conditions hold: Condition 1: The fundamental period of the phase reference generator, T, corresponds to f in equation (0.11), i.e. f=1/T; and, Condition 2: The observed phase error between the PRG and the voltage source V_{dp}(t) is zero at the positive to negative zero crossing of the sinusoidal waveform.

Referring to Equation (11), a fundamental assumption in the present analysis is that the input power source to the weld control is a sinusoidal source of fixed and closely known frequency, but unknown and fixed phase relative to the internal phase reference generator 10. It is also assumed that the voltage modulation term, Vₘ(t) in (11) above is slowly varying, and is effectively a constant over the interval over which the calculations are based.

Phase Reference Generator 10 does not generate a waveform per-se, but the timing of the PRG can be visualized as a square wave of frequency twice that of the fundamental period of the sinusoid it is attempting to track. In this representation, one PRG cycle comprises two cycles of the square wave. This visualization is employed because in the actual implementation of the PRG in a digital signal processor, or DSP it is possible for the DSP to generate the square wave as an output, so it can be observed relative to the sinusoid using an oscilloscope.

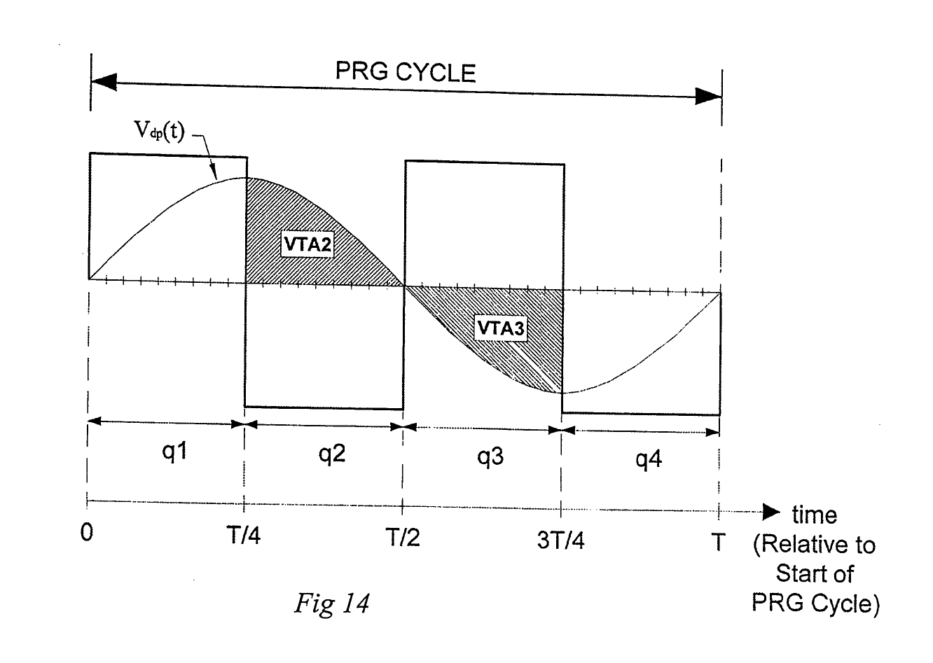

FIG. 14 shows such a representation, along with the input sinusoid, assuming that the phase reference generator is in complete synchronization with the sinusoid. In this visualization, one can see four “transitions” of the phase reference generator for each cycle of the sinusoid, dividing the sinusoid into quadrants, labeled q1, q2, q3 and q4 in FIG. 14. It is important in what follows to keep in mind that the “quadrants” are defined relative to the PRG which may or may not be synchronized with the sinusoid.

An analog to digital converter function of the EQ5400 AC Resistance Weld Control is, by design, synchronized with the PRG and takes a constant number of evenly spaced, samples of the line voltage waveform per internal PRG line cycle. In the actual design of the EQ5400 AC Resistance Weld Control, the analog to digital converter generates 128 such digitized voltage samples per PRG cycle, or 32 samples per quadrant. Assume there is a function resident in the system capable of generating the true, mathematical integral of voltage over each quadrant of the PRG. Of interest in this analysis is the volt-time area over quadrants q2 and q3, which represent the shaded areas VTA2 and VTA3 in FIG. 14. Because a sinusoid has odd symmetry about the 180 degree point, one can visualize from FIG. 14, that when the PRG is synchronized with the sinusoid, the volt-time areas VTA2 and VTA3 are of equal, but opposite sign, so if they are added, the net sum of the volt-time area is zero.

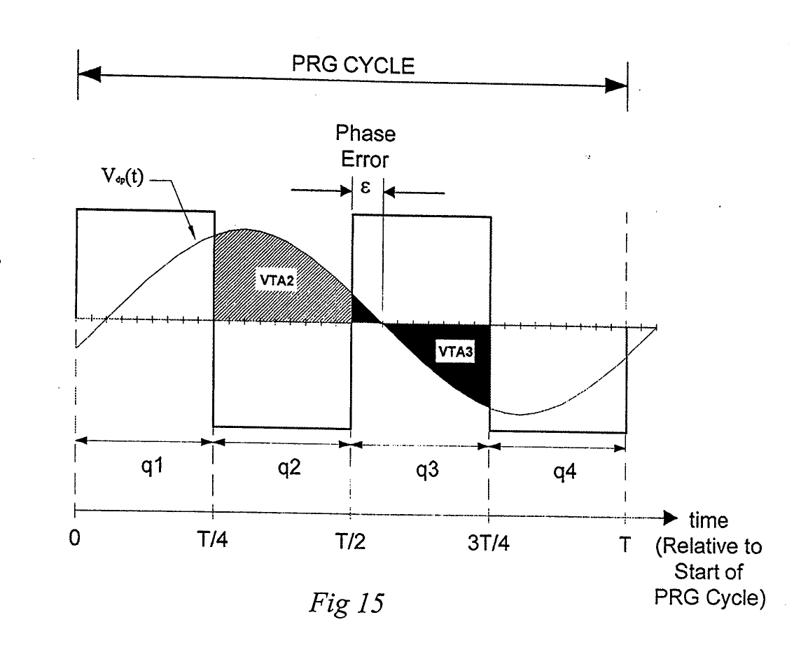

This is not the case when the PRG is not synchronized. FIG. 15 shows a condition in which the positive to negative zero crossing of the input voltage lags the transition from q2 to q3 of the PRG by an angle ε. In this case, it is readily seen that the volt-time areas represented by VTA2 and VTA3 are not of equal magnitude. Comparing FIG. 15 with FIG. 14, one can visualize that when the PRG leads the input voltage, the computed ,magnitude of VTA2 will be larger than that when the PRG is synchronized, and that the computed magnitude VTA3 will be smaller than when it is synchronized. Accordingly, when VTA2 and VTA3 are added as signed quantities with VTA2 positive and VTA3 negative, the result is a positive quantity, indicating the leading characteristic of the PRG with respect to the input voltage. Similarly, it can be envisioned that if the PRG lags the input voltage, the sum of VTA2 and VTA3 will be a negative quantity, indicating a lagging condition.

It will now be demonstrated that for small values of phase error, ε, between the PRG and the input voltage sinusoid, a normalized sum of VTA2 and VTA3 provides a very good direct estimate of the phase error. With respect to FIG. 15, the equation describing the input voltage waveform, V_{dp}(t), with time referred to the PRG is
V_{dp}(t)=Vₘ sin(2πt−ε) (12)
where Vₘ is the fixed amplitude of the voltage sinusoid, f is the frequency of the sinusoid and ε is the phase error between the sinusoid and the PRG. To re-iterate, it is assumed that the frequency is known, and that all three of these values are constant As indicated above, positive ε indicates that the sinusoid lags the PRG or, equivalently, the PRG leads the sinusoid. The fundamental period of the PRG is denoted T, and if it is assumed that the PRG and sinusoid have the same fundamental frequency, T is related to f by:

$$T = \frac{1}{f} \qquad ( 13 )$$

In FIG. 15, the interval q2 is represented as the closed time interval [T/4,T/2]. The interval q3 is represented by the closed interval [T/2,3T/4]. With these intervals defined, the integral of the sinusoid over q2, denoted VTA2, is:

$$\begin{matrix}VTA 2 = {\int }_{T / 4}^{T / 2} V sin ( 2 π f t - ɛ ) ⅆ t \\ {= - \frac{V}{2 π f} cos ( 2 π f t - ɛ ) ]}_{T / 4}^{T / 2}\end{matrix} \qquad ( 14 )$$

Using the relation from plane geometry:
cos(a−b)=cos(a)cos(b)+sin(a)sin(b) (15)
equation (14) becomes simply:

$$VTA 2 = \frac{VT}{2 π} [ cos ( ɛ ) - sin ( ɛ ) ] \qquad ( 16 )$$

Similarly, VTA3 is given by:

$$\begin{matrix}VTA 3 = {\int }_{T / 2}^{3 T / 4} V sin ( 2 π f t - ɛ ) ⅆ t \\ {= - \frac{VT}{2 π} cos ( \frac{2 π}{T} t - ɛ ) ]}_{T / 2}^{3 T / 4} \\ = - \frac{V}{2 π f} ( sin ɛ + cos ɛ )\end{matrix} \qquad ( 17 )$$

Adding VTA2 and VTA3 yields:

$$VTAQ 2 + VTAQ 3 = - \frac{V}{π f} sin ( ɛ ) \qquad ( 18 )$$

while subtracting VTA3 from VTA2 results in:

$$VTA 2 - VTA 3 = - \frac{V}{π f} cos ( ɛ ) \qquad ( 19 )$$

Now, define the quantity ε by

$$E = \frac{VTA 2 + VTA 3}{VTA 2 - VTA 3} \qquad ( 20 )$$

Substituting (16) and (17) for VTA2 and VTA3 and simplifying yields:
E=tan(ε) (21)
which, for small values of phase error, E, becomes as an approximation:
E=tan(ε)≈ε (22)

Thus, for small values of phase error, the quantity E, computed by taking volt-time areas provides a good estimate of the phase error (in radians) under the assumptions given. This phase error estimate can be used in a closed loop feedback system to drive the PRG into synchronization with the line voltage.

As mentioned above, the EQ5400 AC Resistance Weld Control is a sampled data system in which samples of the external continuous time signals are taken at discrete, fixed intervals of time using an analog to digital converter. These samples are, by design, synchronized to the timing of the PRG and, in fact, a PRG period is defined as the time required to obtain 128 such samples in the preferred embodiment. A continuous time signal, x(t) is approximated in a sampled data system by a sequence of discrete sample points, x(k) according to:
x(k)=x(t)|_{t=kT}_{ₛ} (23)
where Tₛ is the elementary sample period of the system—the DSP interrupt interval in the case of the EQ5400 AC Resistance Weld Control. In what follows, the value x(k) refers to the kth elementary sample of the entity x(t). For instance, applying this to the observed voltage waveform of (11) gives the sequence:
V_{dp}(k)=Vₘ sin(2πfkTₛ+φ), k=0, 1, . . . (24)

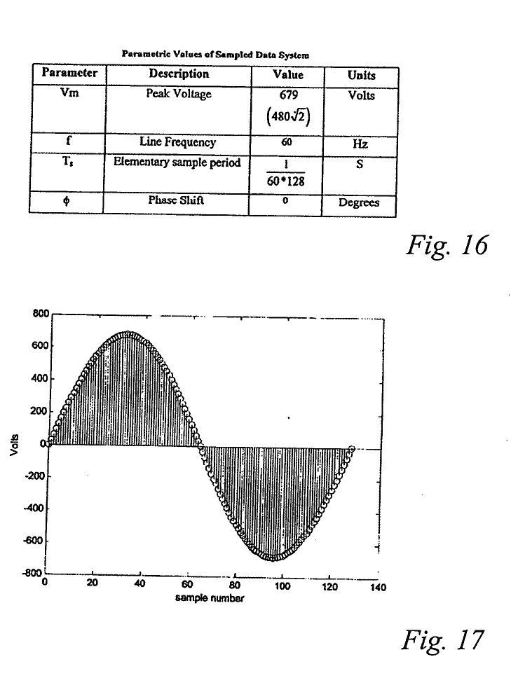

As an example of such a sequence, let the parametric values in (24) be those given in the table shown in FIG. 16. This corresponds to sampling a 480 VRMS, 60 Hz waveform at 128 samples per line cycle. The corresponding samples are shown as a stem plot in FIG. 17.

In the EQ5400 AC Resistance Weld Control, the voltage is sampled at discrete intervals as described above, and a trapezoidal approximation to the volt-time area integral is performed. If the number of samples taken by the digital voltmeter function over an internal PRG period is Nₛ., then there are Nₛ/4 samples taken over a quadrant. The estimates of volt-time area of quadrants 2 and 3, henceforth denoted V_{wc}TA (q2) and V_{wc}TA (q3) are generated using:

$$\begin{matrix}{V}_{wc} TA ( q 2 ) = {T}_{s} {\sum }_{j = \frac{{N}_{s}}{4} + 1}^{\frac{{N}_{s}}{2}} \frac{{V}_{wc} ( j ) + {V}_{wc} ( j - 1 )}{2} \\ and & ( 25 ) \\ {V}_{wc} TA ( q 3 ) = {T}_{s} {\sum }_{j = \frac{{N}_{s}}{2} + 1}^{\frac{3 {N}_{s}}{2}} \frac{{V}_{wc} ( j ) + {V}_{wc} ( j - 1 )}{2} & ( 26 )\end{matrix}$$

Here, the index “j” refers to the jth sample of the voltage waveform (DSP interrupt) within a PRG cycle as defined above.

In a resistance weld application, in which large currents are drawn for short periods, the presence of line impedance corrupts the “shape” of the observed voltage, so that it is no longer sinusoidal. The following develops the current equation for an AC phase controller, such as a resistance welder, and explores the effects of the line impedance on the observed sinusoid.

The mathematical solution is developed in two parts. First, the current equation of a stiff driving point voltage source driving a load that has both resistive and inductive components is explored. Next, resistive and inductive line impedance elements are introduced in series between the driving point voltage source and the point at which the voltage is actually observed, and the relation between the driving point voltage and the actual voltage observed by the weld control are explored.

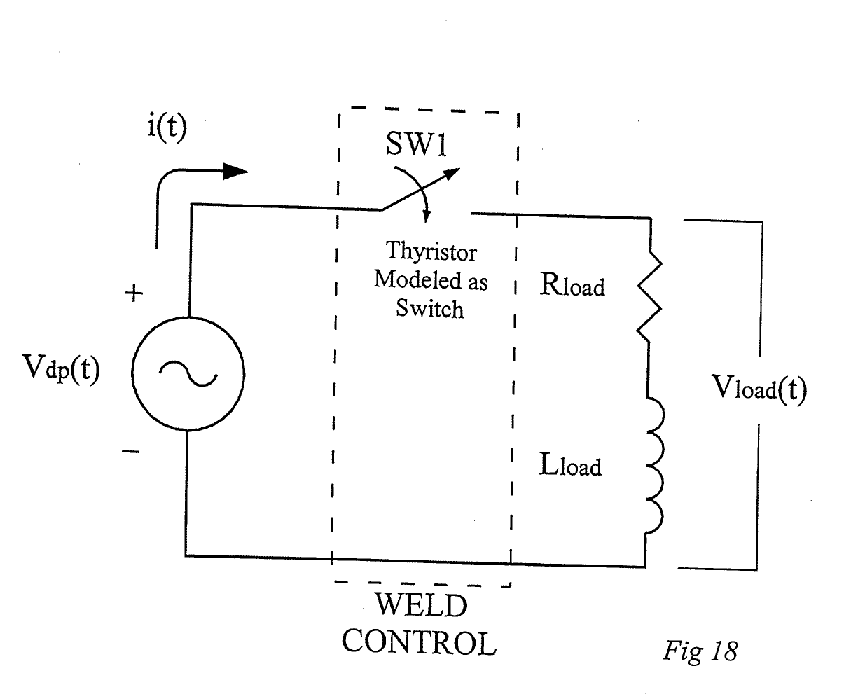

FIG. 18 shows an ideal circuit model for an AC phase control, such as a resistance welder, driving an inductive load. An ideal source of voltage, labeled V_{dp}(t), provides the source voltage for the system. A switch, labeled SW1, closes and opens on demand, and represents the thyristors that form the solid state switching elements of the phase control. The load comprises a resistor, labeled R_{load} and an inductor, labeled L_{load}. The current flowing is labeled i(t), and the voltage applied to the load is labeled V_{load}(t).

As above, in this first scenario, V_{dp}(t) is a sinusoidal voltage source of the form:
V_{dp}(t)=Vₘ sin(ωt) (27)
where ω is the radian frequency of the sinusoid, related to the frequency in Hz. by:
ω=2πf (28)

When a semiconductor switch such as an SCR is used as the switching device, a simple model for this device is a switch closing at a commanded time τ from the zero crossing of the sinusoidal voltage source. Once the switch is closed and current begins to flow, it continues to flow until the current naturally extinguishes itself, at which time the switch blocks voltage. Under this condition, the current flowing in the circuit is given as a function of time by:

$$i ( t ) = ( \frac{V}{\sqrt{{R}_{load}^{2} + {( ω {L}_{load} )}^{2}}} ) [ \begin{matrix}s in ( ω t - ϕ ) - \\ {ⅇ}^{- \frac{ {R}_{ load}}{ {L}_{ load}} ( t - τ )} sin ( ω τ - ϕ )\end{matrix} ] [ \begin{matrix}u ( t - τ ) - \\ u ( t - ( τ + T ) )\end{matrix} ] \qquad ( 29 )$$

where φ is referred to as the “lag angle”, related to the resistance and inductance by:

$$ϕ = {tan}^{- 1} ( \frac{ω {L}_{load}}{{R}_{load}} ) \qquad ( 30 )$$

and T is the conduction time, i.e. the time elapsed from the firing time until the current naturally extinguishes itself, expressed concisely mathematically by:

$$T = {min ( t - τ )}_{t > τ , i ( t ) = 0} \qquad ( 31 )$$

The function u(t) is the commonly known “unit step function”, defined mathematically by:

$$u ( t ) = \{ \begin{matrix}0 , & t \leq 0 \\ 1 , & t > 0\end{matrix} \qquad ( 32 )$$

The origins of equation (29) and it's derivation will be discussed subsequently.

In general, equation (29) cannot be solved in closed form for conduction time, but iterative methods can be used to derive approximations. Equation (29) can be normalized to be frequency and therefore time independent. Define the firing angle α, conduction angle, γ and impedance Z_{load} of the phase control by:
α=ωτ (33)
γ=ωT (34)
and
Z_{load}=\sqrt{R_{load}²+(ωL_{load})²} (35)
and let θ be the observation angle, i.e. the angle after the zero crossing of the sinusoid. Then (29) becomes:

$$i ( θ ) = ( \frac{V}{\vert {Z}_{load} \vert} ) [ sin ( θ - ϕ ) - {ⅇ}^{- \frac{( θ - α )}{tan ( ϕ )}} sin ( α - ϕ ) ] [ u ( θ - α ) - u ( θ - ( α + γ ) ) ] \qquad ( 36 )$$

This is the “normalized” form of the phase control equation.

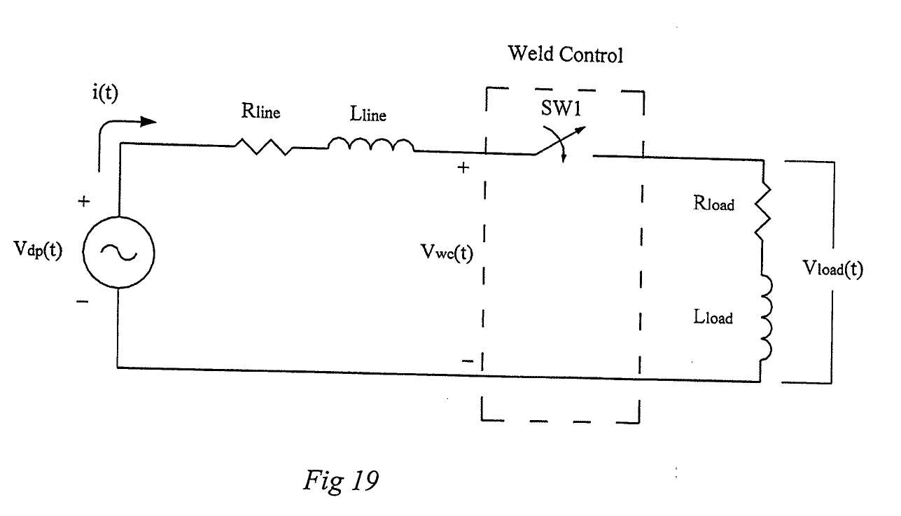

Next, consider a more complex circuit model of the lumped parameter system that forms the mathematical basis for the present invention. In this model, shown in FIG. 19, the source of weld power is not assumed “stiff” as in the previous discussion, but contains three lumped circuit elements, namely: the original “stiff” driving point voltage source V_{dp}(t), identical to that above and a series lumped line resistance, labeled Rₗᵢₙₑ; and series lumped line inductance, labeled Lₗᵢₙₑ inserted between the driving point voltage source and the weld control.

This lumped parameter model of the power source combines the resistance from all sources between the assumed stiff voltage source and the input terminals of the weld control. It includes the winding resistance of the distribution transformer, the inductance of the transformer, the resistance and inductance of the power distribution system, such as wires, busway, switch contacts, etc. This line impedance can be significant with respect to the load impedance. In FIG. 19, the voltage observed by the weld control is labeled V_{wc}(t) and, under conditions in which the weld control is firing under load, differs from V_{dp}(t) by virtue of the current flowing through Rₗᵢₙₑ and Lₗᵢₙₑ.

Referring to FIG. 19, several things are apparent: both the line impedance and load impedance factor into determining the weld current, i(t); when there is no current flowing, and hence no voltage drop across the line impedance, the voltage observed by the weld control, V_{wc}(t), is equal to the source voltage, V_{dp}(t). However, when current is flowing in the circuit, the voltage observed by the weld control is not that of the voltage source, V_{dp}(t), because of voltage drops across the line resistance and line inductance.

From elementary circuit analysis, one can write for the current:

$$i ( t ) = ( \frac{V}{\sqrt{{R}_{eq}^{2} + {( ω {L}_{eq} )}^{2}}} ) [ \begin{matrix}sin ( ω t - ϕ ) - \\ {ⅇ}^{- \frac{{R}_{eq}}{ {L}_{eq}} ( t - τ )} sin ( ωτ - ϕ )\end{matrix} ] [ \begin{matrix}u ( t - τ ) - \\ u ( t - ( τ + T ) )\end{matrix} ] \qquad ( 37 )$$

where R_{eq} and L_{eq} are, in this case, the equivalent series resistance and inductance, given by:
R_{eq}=Rₗᵢₙₑ+R_{load} (38)
and
L_{eq}=Lₗᵢₙₑ+L_{load} (39)
and φ, and T are computed per the equations describing the simple model of FIG. 18, but using the equivalent values above. The voltage V_{wc}(t), observed by the weld control is related to the ideal voltage source modeled by V_{dp}(t) by:

$${V}_{wc} ( t ) = {V}_{dp} ( t ) - {R}_{line} i ( t ) - {L}_{line} \frac{ⅆ i ( t )}{ⅆ t} \qquad ( 40 )$$

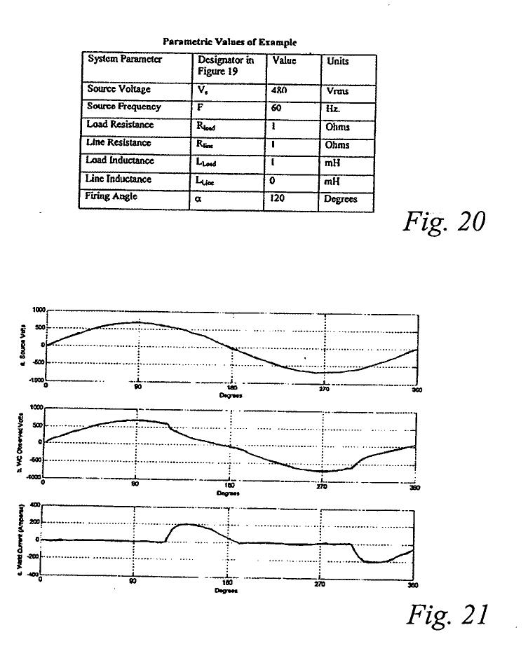

The voltage observed by the voltmeter function of the weld control becomes quite complex, and it is difficult to visualize the effect. However, FIG. 21 shows simulation results showing the effect of the line resistance and line inductance on the observed voltage for the parametric values of the circuit in FIG. 19, provided in the table shown in FIG. 20. The simulation and charts presented were generated using MATLAB, a commercially available software package well suited to the task.

Comparing the voltage waveform of the driving point voltage source in FIG. 21 (top) with the voltage waveform that would be observed by the voltmeter function of the weld control in FIG. 21 (middle), the observed voltage waveform is a significantly distorted version of the source voltage. Under load, the weld control cannot directly observe the driving point voltage source, V_{dp}(t), because it is strictly a mathematical construct, and as such there is no specific point on which to apply connections to measure voltage. Even if one could find an appropriate point in the power distribution system to monitor the actual source voltage, the monitor point would likely be located some distance from the weld control, and it is desirable to have the weld control a localized, stand alone entity. The EQ5400 AC Resistance Weld Control observes the voltage at the input terminals.

The voltage distortion shown in FIG. 21 limits the performance of an AC resistance weld control in two ways without the benefit of the present invention. The first limitation is that applying the method of estimating phase discussed in detail above to the distorted waveform of FIG. 21 (middle) generates an incorrect estimate of the phase relative to the driving point voltage source. For the example above, using the phase error estimation method provided above, it can be shown that if the phase reference generator were originally “locked” onto the line voltage source V_{dp}(t) (the term “locked” meaning zero phase error generated prior to welding), applying the same method to the observed weld control voltage, V_{wc}(t) of FIG. 21 (middle) while welding, the phase error estimator gives a phase error of approximately −7.7 degrees. If the PRG is allowed to react to this estimated error while welding, the timing of the system will be incorrect, and the system will generate the wrong firing points for the thyristors to achieve a target weld current. Even if closed loop control is employed to modify the firing points to obtain a constant current, reacting to the phase error generated above would at least cause a disturbance in the weld current. Since resistance welds are typically short (on the order of ten line cycles total), such a disturbance could have an effect on the metallurgy of the weld.

The second limitation is that the RMS voltage measured by the weld control in FIG. 21 is less than that of the driving point voltage source model V_{dp}(t). In the example given, whereas the RMS value of the voltage source is 480 Volts, the RMS voltage of the waveform in FIG. 21 (middle) is 453 Volts. This is the waveform that is directly observed by the weld control. One feature of some prior art weld controls is the ability to automatically compensate for variations in observed voltage, attempting to maintain the current constant. From the above development of the weld current equation of a system with line resistance and reactance, it is clear that the current delivered for a given firing point of the thyristor is dependent upon the driving point voltage and the equivalent, lumped resistance and inductance, which include the load and line values. Accordingly, using the observed line voltage (which differs from the driving point voltage when current is flowing) as the basis for voltage compensation presents a limitation to the weld control performance. Conversely, the ability to use the estimated driving point voltage described in the present invention, as the basis for line voltage compensation affords an important improvement in this regard.

The effectiveness of a weld control based on the circuit model of FIG. 19 to generate appropriate thyristor firing points (timing) is dependent upon the accuracy upon which the PRG can estimate the relative phase error between itself and the mathematical model of driving point source voltage. As has been discussed, the very act of conducting current in a resistance weld distorts the voltage waveform observed by the weld control, and directly applying the method of discussed above to the observed voltage will cause errors in timing of the firing of the thyristors.

Suppose, however, that the parametric values of line resistance and line reactance (inductance) can be estimated. If this is so, then from equation (40), and an observation of the weld control voltage V_{wc}(t) at the input of the weld control, the load current i(t), and the derivative of load current, di(t)/dt, an estimate of the open circuit ideal voltage source, V*_{dp}(t), can be made using:

$${V}_{dp}^{*} ( t ) = {V}_{wc} ( t ) + {R}_{line}^{*} i ( t ) + {L}_{line}^{*} \frac{ⅆ i ( t )}{ⅆ t} \qquad ( 41 )$$

Applying the mathematics above to estimate the source voltage V*_{dp}(t) and subsequently using this estimated voltage in computing the phase error in the PRG should provide for more accurate timing of the PRG and hence the firing points of the thyristors, and would more generally facilitate use of the model of FIG. 19 in a feed-forward control scheme. Accordingly, one feature of the present invention is a means to estimate the line resistance and line reactance of the power distribution system.

To proceed in developing the mathematics, one can solve equation (40) for V_{dp}(t) to obtain:

$${V}_{dp} ( t ) = {V}_{wc} ( t ) + {R}_{line} i ( t ) + {L}_{line} \frac{ⅆ i ( t )}{ⅆ t} \qquad ( 42 )$$

Note that this relation is independent of the values of the load impedance elements, R_{load} and L_{load}. As discussed above, the weld control includes a digital voltage sampling function (analog to digital converter) that can estimate (measure) V_{wc}(t), at discrete intervals and a digital current sampling function that can similarly estimate the value of i(t) at discrete intervals. If values of Rₗᵢₙₑ and Lₗᵢₙₑ can be estimated, equation (42) indicates that the instantaneous driving point voltage, V_{dp}(t) can also be estimated.

As stated previously, the EQ5400 AC Resistance Weld Control operates as a sampled data system, sampling the signals representative of voltage and current at discrete intervals, at the sequence of points {tₖ}, defined by:
tₖ=kTₛ
where Tₛ is the elementary sampling interval. Applying this to equation (42) yields a sequence of points, V_{dp}(k), with the kth sample in the sequence given by:

$${V}_{dp} ( {kT}_{s} ) = {V}_{wc} ( {kT}_{s} ) + {R}_{line} i ( {kT}_{s} ) + {L}_{line} \frac{ⅆ i ( {kT}_{s} )}{ⅆ t} , \\ k = 0 , 1 , … \qquad ( 43 )$$

Henceforth, it is understood that whenever the index “k” appears, the corresponding time of the sample is t=kT, k=0, 1, 2, . . . ₛ. With this understood, the nomenclature in equation (43) above is simplified to yield:

$${V}_{dp} ( k ) = {V}_{wc} ( k ) + {R}_{line} i ( k ) + {L}_{line} \frac{ⅆ i}{ⅆ t} ( k ) , \\ k = 0 , 1 , … \qquad ( 44 )$$

The weld control provides sampling functions that provide estimates of the voltage sequence V_{wc}(k) and the current i(k), but not the derivative sequence di(k)/dt at each point. However, an approximation to the derivative sequence can be made by defining the first backward difference, Δi(k):
Δi(k)=i(k)−i(k−1) (45)
and approximating the derivative using

$$\frac{ⅆ i}{ⅆ t} ( k ) \approx \frac{Δ i ( k )}{{T}_{s}} \qquad ( 46 )$$

substituting (46) into (44) gives:

$${V}_{dp} ( k ) = {V}_{wc} ( k ) + {R}_{line} i ( k ) + {L}_{line} \frac{Δ i ( k )}{{T}_{s}} , \\ n = 0 , 1 , … \qquad ( 47 )$$

Now, define X_{leq} by:

$${X}_{leq} = \frac{{L}_{line}}{{T}_{s}} \qquad ( 48 )$$

where Tₛ is the known sample period of the system. Substituting this gives:
V_{dp}(k)=V_{wc}(k)+Rₗᵢₙₑi(k)+X_{leq}Δi(k), k=0, 1, . . . (49)
Some methods of estimating the assumed constant values of Rₗᵢₙₑ and X_{leq} are now explored. To accomplish this, the development will begin with a general approach and preferred method evolved. Examining equation (49), at a given sample, k, there are three quantities that can be “known” to the system via measurements, namely 1) V_{wc}(k) which can be measured using the digital voltmeter function, 2) i(k), which can also be measured using the digital current meter function, and 3) Δi(k) which can be computed from a knowledge of i(k) and i(k−1) according to equation (45). There are also three unknowns in the equation, namely V_{dp}(k), Rune and Xleq. None of these are directly observable when current is flowing, and the sequence V_{dp}(k) is not necessarily constant. There are several ways in which one can proceed to generate an estimate of Rₗᵢₙₑ and X_{leq}, but in each case some assumptions must be made regarding the nature of V_{dp}(k) which is also not directly observable.

One possible method to estimate the constant values of Rₗᵢₙₑ and X_{leq} is to suppose the system has obtained observations of the measurable quantities at distinctive sample times k0, k1 and k2 (not necessarily in monotonic increasing order), and further suppose that that there is a known, constant mathematical relation between the values of V_{dp}(k1), V_{dp}(k2) and V_{dp}(k3) that can be expressed as:

$$[ \begin{matrix}{V}_{dp} ( k 1 ) \\ {V}_{dp} ( k 2 )\end{matrix} ] = [ \begin{matrix}{M}_{1} \\ {M}_{2}\end{matrix} ] {V}_{dp} ( k 0 ) \qquad ( 50 )$$

where M₁ and M₂ are known constants. With this established, one can write the following matrix equation for the three samples:

$$[ \begin{matrix}{V}_{wc} ( k 0 ) \\ {V}_{wc} ( k 1 ) \\ {V}_{wc} ( k 2 )\end{matrix} ] = [ \begin{matrix}- i ( k 0 ) & - Δ i ( k 0 ) & 1 \\ - i ( k 1 ) & - Δ i ( k 1 ) & {M}_{1} \\ - i ( k 2 ) & - Δ i ( k 2 ) & {M}_{2}\end{matrix} ] [ \begin{matrix}{R}_{line} \\ {X}_{leq} \\ {V}_{dp} ( k 0 )\end{matrix} ] \qquad ( 51 )$$

which is of the form:
V=A*U (52)
where V is the matrix of measured voltage points:

$$V = [ \begin{matrix}{V}_{wc} ( k 0 ) \\ {V}_{wc} ( k 1 ) \\ {V}_{wc} ( k 2 )\end{matrix} ] , \qquad ( 53 )$$

U is the matrix of unobservable quantities (two of which, Rₗᵢₙₑ and X_{leq} are the object of this estimation):

$$U = [ \begin{matrix}{R}_{line} \\ {X}_{leq} \\ {V}_{dp} ( k 0 )\end{matrix} ] \qquad ( 54 )$$

and A is a matrix of observable and known quantities relating V and U according to (51):

$$A = [ \begin{matrix}- i ( k 0 ) & - Δ i ( k 0 ) & 1 \\ - i ( k 1 ) & - Δ i ( k 1 ) & {M}_{1} \\ - i ( k 2 ) & - Δ i ( k 2 ) & {M}_{2}\end{matrix} ] \qquad ( 55 )$$

If the matrix A is non-singular, the mathematical inverse of A exists and one could solve (51) to obtain:

$$[ \begin{matrix}{R}_{line} \\ {X}_{leq} \\ {V}_{dp} ( k 0 )\end{matrix} ] = {[ \begin{matrix}- i ( k 0 ) & - Δ i ( k 0 ) & 1 \\ - i ( k 1 ) & - Δ i ( k 1 ) & {M}_{1} \\ - i ( k 2 ) & - Δ i ( k 2 ) & {M}_{2}\end{matrix} ]}^{- 1} [ \begin{matrix}{V}_{wc} ( k 0 ) \\ {V}_{wc} ( k 1 ) \\ {V}_{wc} ( k 2 )\end{matrix} ] \qquad ( 56 )$$

and thus obtain an estimate of Rₗᵢₙₑ and X_{leq}. Equation (56) will also yield the value of V_{dp}(k0), but the most important quantities for the present invention are the line resistance and reactance.

One interesting variation on this method is to assume that the sequence V_{dp}(k) is periodic in k with an integer period Nₛ, such that:
V_{dp}(pNₛk)=V_{dp}(k) (57)
For values of p in the set of natural numbers, i.e. p={1, 2, . . . }. This is interesting from the perspective of the present invention because 1) it is already assumed that the driving point voltage is periodic, and 2) as discussed earlier a PRG period comprises Nₛ samples (DSP interrupts). Thus, if the PRG is already synchronized with the driving point voltage this periodic relation exists and is known. If k0, k1 and k2 are related by:

$$[ \begin{matrix}k 1 \\ k 2\end{matrix} ] = [ \begin{matrix}p 1 \\ p 2\end{matrix} ] N * k 0 , p 1 , p 2 \neq 1 , p 1 \neq p 2 \qquad ( 58 )$$

With p1 and p2 both natural numbers, then from (57) this yields M₁=1 and M₂=1 in equation (56). Practically, this method implies that the samples are taken at the same relative “place” in different PRG cycles. Of course, being able to set M₁ and M₂=1 in equation (56) does nothing to guarantee that the matrix is non-singular and can be inverted, so this method may not work in a general case. In particular, if the system employing such a method is operating in the “steady state”, such that the current and current difference taken at the same at each sample point, the matrix will definitely be singular and the method will not produce useful estimates of Rₗᵢₙₑ and X_{leq}.

To explore a different, and more practical means for estimating Rₗᵢₙₑ and X_{leq}, rewrite equation (49) in the form:
V_{dp}(k)−V_{wc}(k)=Rₗᵢₙₑi(k)+X_{leq}Δi(k), k=1, . . . (59)
Now, one can write in matrix form for the three data samples:

$$[ \begin{matrix}{V}_{dp} ( k 0 ) - {V}_{wc} ( k 0 ) \\ {V}_{dp} ( k 1 ) - {V}_{wc} ( k 1 ) \\ {V}_{dp} ( k 2 ) - {V}_{wc} ( k 2 )\end{matrix} ] = [ \begin{matrix}i ( k 0 ) & Δ i ( k 0 ) \\ i ( k 1 ) & Δ i ( k 1 ) \\ i ( k 2 ) & Δ i ( k 2 )\end{matrix} ] [ \begin{matrix}{R}_{line} \\ {X}_{leq}\end{matrix} ] , k = 1 , … \qquad ( 60 )$$

Significant simplification in the mathematics above can be made if one assumes that during one of the samples, say k0, the current and current difference are both zero. If this is the case, from equation (60), one can write directly:
V_{wc}(k0)=V_{dp}(k0) (61)
and if (57) still applies, one can write

$$[ \begin{matrix}{V}_{wc} ( k 0 ) - {V}_{wc} ( k 1 ) \\ {V}_{wc} ( k 0 ) - {V}_{wc} ( k 2 )\end{matrix} ] = [ \begin{matrix}i ( k 1 ) & Δ i ( k 1 ) \\ i ( k 2 ) & Δ i ( k 2 )\end{matrix} ] [ \begin{matrix}{R}_{line} \\ {X}_{leq}\end{matrix} ] \qquad ( 62 )$$

Which can be solved for the line resistance and reactance:

$$[ \begin{matrix}{R}_{line} \\ {X}_{leq}\end{matrix} ] = {[ \begin{matrix}i ( k 1 ) & Δ i ( k 1 ) \\ i ( k 2 ) & Δ i ( k 2 )\end{matrix} ]}^{- 1} [ \begin{matrix}{V}_{wc} ( k 0 ) - {V}_{wc} ( k 1 ) \\ {V}_{wc} ( k 0 ) - {V}_{wc} ( k 2 )\end{matrix} ] \qquad ( 63 )$$

This too assumes that the matrix of current and current difference is non-singular, but is only a 2×2 matrix.

The assumption that a line cycle can be found in which current does not flow and has not been flowing (so the current and current difference are both zero at the point k1) is a reasonable one in a resistance welding application in which the application of weld current is normally preceded by a period in which current does not flow while the mechanical weld “tips” force the metal to be joined together. Furthermore, once current begins to flow, it can be reasonably certain that the current flowing in the first line cycle of weld will differ from subsequent line cycles of current because this forcing of metal together is normally not perfect and the steady state will not be reached until the metal actually begins to melt.

To continue the evolution, if it is assumed that samples can be taken on a PRG cycle in which current is known to not be flowing, and in other PRG cycles in which current is known to be flowing, there is no need to constrain all the samples by equation (57), provided samples can be taken in pairs (ka,kb), such that
k_{b}=pNₛkₐ (64)
In particular, assume there are two pairs of data points, (k₀₁,k₁) and (k₀₂,k₂), such that:
k₁=p₁Nₛk₀₁, p₁≠0 (65)
and
k₂=p₂Nₛk₀₂, p₂≠0 (66)
And that k₀₁ and k₀₂ are samples taken from a PRG cycles in which current is not flowing, and k₁ and k₂ are taken from PRG cycles in which current is flowing, and furthermore assume that (57) applies for each pair (k₀₁,k₁) and (k₀₂,k₂). Then one can write by inspection:

$$[ \begin{matrix}{R}_{line} \\ {X}_{leq}\end{matrix} ] = {[ \begin{matrix}i ( {k}_{1} ) & Δ i ( {k}_{1} ) \\ i ( {k}_{2} ) & Δ i ( {k}_{2} )\end{matrix} ]}^{- 1} [ \begin{matrix}{V}_{wc} ( {k}_{01} ) - {V}_{wc} ( {k}_{1} ) \\ {V}_{wc} ( {k}_{02} ) - {V}_{wc} ( {k}_{2} )\end{matrix} ] \qquad ( 67 )$$

assuming again that the matrix inverse in (67) exists. This method permits (but does not require) the estimation of Rₗᵢₙₑ and X_{leq} to be made from distinct DSP samples within two line cycles, one in which current is not flowing, and one in which current flows. Allowing this greatly enhances the likelihood that the matrix inverse in (67) will exist.

In a factory environment, the magnitude of the actual driving point voltage does change over time, and such a change is one factor that can affect the accuracy of the estimates of line resistance and line reactance. The farther apart in time the line cycles are chosen in the above discussion, the more likely the driving point voltage magnitude will differ significantly. Therefore, in the preferred embodiment of the invention disclosed herein, adjacent line cycles are chosen such that the line cycle in which current flows and is measured is adjacent to a sequence of line cycles in which current has not been flowing for a substantial number of line cycles. It is understood in what follows that this particular embodiment does not limit the usefulness of the invention and in particular, one can readily envision an embodiment in which the line resistance and line reactance are computed using a sequence in which current is flowing in a particular line cycle and does not flow in a subsequent line cycle. The embodiment of the invention disclosed herein is preferred because if current has not been flowing for significant number of line cycles prior to conducting current, the PRG should be accurately synchronized with the driving point voltage when current begins to flow. Because there is a natural lag in response of one line cycle in the PRG implementation disclosed, the current samples taken from the first line cycle in which current flows after a long interval in which current is not flowing cannot affect the PRG until after the measurements are taken. This is the ideal condition in which to obtain samples.

Proceeding again, make the following assumptions: (1) the system has not been welding for a period of time, so that the observed weld control voltage, V_{wc}(t) is identical to that of the source voltage, V_{dp}(t), i.e.
V_{wc}(t)=V_{dp}(t)|ᵢ₌₀ (68)
and (2)over the period of any two line cycles, the modulation term of the driving point voltage, Vₘ(t) is constant, and can be represented as:
V_{dp}(t)=Vₘ sin(2πft) (69)
as above.

Consider two sample points taken exactly one period apart under these conditions: one in which weld current is not flowing, and another, exactly one PRG period apart where current does flow. Recall again from above that there are Nₛ samples (DSP interrupts) per PRG period. Under the assumptions above, one may write:

$${V}_{dp} ( k ) = {V}_{dp} ( k - {N}_{s} ) = {V}_{wc} ( k - {N}_{s} ) {\vert}_{{i ( k - 1 ) = 0}_{Δ i ( k - 1 ) = 0}} \qquad ( 70 )$$

Applying this to equation (49), one can write:
V_{wc}(k−Nₛ)=V_{wc}(k)+Rₗᵢₙₑi(k)+X_{leq}Δi(k), n=0, 1, . . . (71)
for the particular case in which current does not flow during one line cycle and does flow on the subsequent line cycle. If one can select two sets of samples from adjacent line cycles, say at samples k1 and k2 (k1 not equal to k2) in which the current and current difference values are non-zero and are distinctly different from one another, one can write in matrix form:

$$[ \begin{matrix}{V}_{wc} ( k 1 - {N}_{s} ) \\ {V}_{wc} ( k 2 - {N}_{s} )\end{matrix} ] = [ \begin{matrix}{V}_{wc} ( k 1 ) \\ {V}_{wc} ( k 2 )\end{matrix} ] + {R}_{line} [ \begin{matrix}i ( k 1 ) \\ i ( k 2 )\end{matrix} ] + {X}_{leq} [ \begin{matrix}Δ i ( k 1 ) \\ Δ i ( k 2 )\end{matrix} ] \qquad ( 72 )$$

which can be solved in matrix form to obtain:

$$[ \begin{matrix}{R}_{line} \\ {X}_{leq}\end{matrix} ] = {[ \begin{matrix}i ( k 1 ) & Δ i ( k 1 ) \\ i ( k 2 ) & Δ i ( k 2 )\end{matrix} ]}^{- 1} [ \begin{matrix}{V}_{wc} ( k 1 - {N}_{s} ) - {V}_{wc} ( k 1 ) \\ {V}_{wc} ( k 2 - {N}_{s} ) - {V}_{wc} ( k 2 )\end{matrix} ] \qquad ( 73 )$$

provided the inverse matrix is non-singular. Equation (73) provides one means in which the line impedance parameters could be estimated.

A potential limitation with using individual points to make the line impedance parameter estimates is that the observed signals are generally “noisy”, especially in a factory environment where there is a lot of switching on and off of control and power circuits, and other switching elements. The computed values of line resistance and line reactance are sensitive to the actual values of current and voltage used in Equation (73).

A more robust means of estimating the parameters is now presented. As set forth above, the system generates for each quadrant the VTA with trapezoidal integration employed to give the quadrant estimate. It is well understood in the study of stochastic processes that if signals are corrupted by uncorrelated, zero-mean noise, taking the average over a sum of many samples reduces the variance of the estimate. The volt-time area, current-time area and current-difference area can be used to compute such an estimate. For a general sequence x(k), define the general “X-time area”, XTA(q,n) of x(k) over quadrant q, q=q1, q2, q3, q4, and PRG line cycle n by:

$$XTA ( q , n ) = {\sum }_{j = \frac{( q - 1 ) {N}_{s}}{4} + 1}^{\frac{{qN}_{s}}{4}} \frac{x ( j ) + x ( j - 1 )}{2} \qquad ( 74 )$$

where j is the index of the sequence x(k), but indexed from the beginning of the PRG cycle, i.e. j=0 corresponds to the transition from q4 to q1 of the PRG function 10. With this definition, the estimated volt-time area of the observed weld voltage over quadrant q, V_{wc}TA(q,n) is

$${V}_{wc} TA ( q , n ) = {\sum }_{j = \frac{( q - 1 ) {N}_{s}}{4} + 1}^{\frac{{qN}_{s}}{4}} \frac{{V}_{wc} ( j ) + {V}_{wc} ( j - 1 )}{2} \qquad ( 75 )$$

which is exactly the sum used to compute the volt-time area of the quadrants employed in the PRG function 10. Now, In an exactly analogous manner, define V_{dp}TA(q,n), ITA(q,n) and ΔITA(q,n) by:

$$\begin{matrix}{V}_{dp} TA ( q , n ) = {\sum }_{j = \frac{( q - 1 ) {N}_{s}}{4} + 1}^{\frac{{qN}_{s}}{4}} \frac{{V}_{dp} ( j ) + {V}_{dp} ( j - 1 )}{2} & ( 76 ) \\ ITA ( q , n ) = {\sum }_{j = \frac{( q - 1 ) {N}_{s}}{4} + 1}^{\frac{{qN}_{s}}{4}} \frac{i ( j ) + i ( j - 1 )}{2} \\ and & ( 77 ) \\ Δ ITA ( q , n ) = {\sum }_{j = \frac{( q - 1 ) {N}_{s}}{4} + 1}^{\frac{{qN}_{s}}{4}} \frac{Δ i ( j ) + Δ i ( j - 1 )}{2} & ( 78 )\end{matrix}$$

Next, observe that equation (49) is a linear equation that, for each sample n relates the driving point voltage sample V_{dp}(k) to the observed weld voltage sample, V_{wc}(k), current sample i(k), and first current difference Δi(k). Since it is a linear relationship, the relationship also applies equally to the quantities XTA(q):
V_{dp}TA(q,n)=V_{wc}TA(q,n)+RₗᵢₙₑTA(q,n)+X_{leq}ΔTA(q,n) (79)
with Rₗᵢₙₑ and X_{leq} assumed constant parameters.

Selecting q2 and q3 as the quadrants to be used to estimate the parameters, one obtains (in matrix form):

$$[ \begin{matrix}ITA ( q 2 , n ) & Δ ITA ( q 2 , n ) \\ ITA ( q 3 , n ) & Δ ITA ( q 3 , n )\end{matrix} ] [ \begin{matrix}{R}_{line}^{*} \\ {X}_{line}^{*}\end{matrix} ] = \\ [ \begin{matrix}{V}_{wc} TA ( q 2 , n - 1 ) - {V}_{wc} TA ( q 2 ) \\ {V}_{wc} TA ( q 3 , n - 1 ) - {V}_{wc} TA ( q 3 )\end{matrix} ] \qquad ( 80 )$$

where the nomenclature R*ₗᵢₙₑ and X*_{leq} refer to the estimates of power distribution system resistance and inductance respectively, and the indices (q2,n) and (q3,n) mean the quadrant estimates from quadrants 2 and 3 of the present line cycle in which current is flowing, and (q2,n−1)and (q3,n−1) designate the quadrants 2 and 3 from the previous line cycle, in which current was not flowing. Again, one can solve for the estimated parameters to obtain:

$$[ \begin{matrix}{R}_{line}^{*} \\ {X}_{leq}^{*}\end{matrix} ] = {[ \begin{matrix}ITA ( q 2 , n ) & Δ ITA ( q 2 , n ) \\ ITA ( q 3 , n ) & Δ ITA ( q 3 , n )\end{matrix} ]}^{- 1} [ \begin{matrix}{V}_{wc} TA ( q 2 , n - 1 ) - {V}_{wc} TA ( q 2 , n ) \\ {V}_{wc} TA ( q 3 , n - 1 ) - {V}_{wc} TA ( q 3 , n )\end{matrix} ] \qquad ( 81 )$$

This important result is the method utilized in line impedance parameter estimation in the EQ5400 AC Resistance Weld Control to compute the values R*ₗᵢₙₑ(m) and X*_{leq}(m) in FIG. 8 above.

A closed form solution to the weld current delivered by an AC resistance weld control is now developed using Laplace Transform techniques. The analysis assumes a stiff driving point voltage source and ideal thyristor switches. Results are presented both as a function of time as well as observation angle. The conditions determining the time or angle of conduction of the thyristor as a function of the firing point and load impedance are also presented.

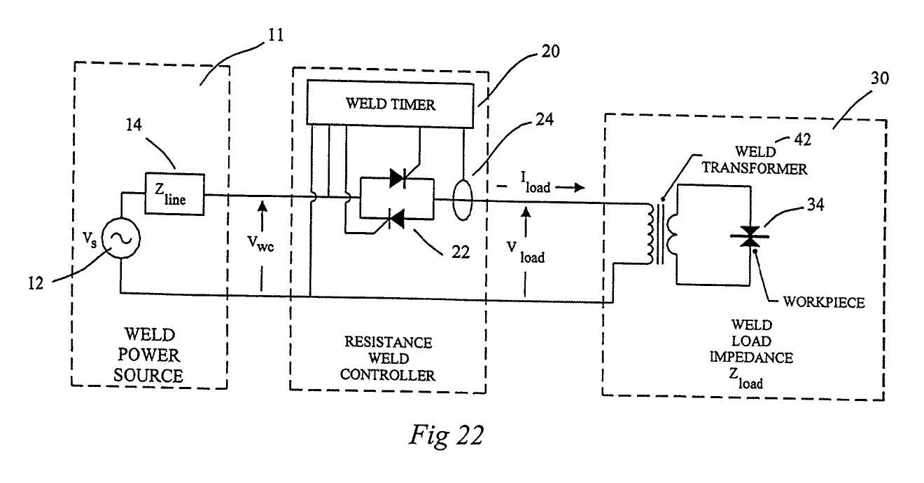

FIG. 22 is a simplified lumped parameter circuit model for a resistance weld controller and associated power distribution system and weld load, which will be used to derive mathematics of the weld controller. The lumped parameter model comprises a weld power source 11, the weld controller 20 and weld load impedance 30. The weld power source 11 is modeled as two circuit elements, a voltage source Vₛ(t) 12, which is assumed to be an ideal voltage source having no series impedance and a serially connected lumped line impedance, Zₗᵢₙₑ, which is assumed to be ideal and linear and which generates a voltage drop between the ideal voltage source and the weld control proportional to the weld load current. The weld timer 20 is capable of observing the load current I_{load} via a current transformer 24 and the voltage applied at its input terminals, V_{wc}(t). Utilizing solid state thyristor switches 22, the weld timer generates a weld voltage V_{load}(t) at its output terminals, with a corresponding weld current I_{load}(t). The weld load impedance 44 comprises the weld transformer 20, workpiece, tooling 22, fixtures and other sources of impedance. To simplify the mathematics, the impedance of all these elements are lumped into a single impedance quantity reflected at the output terminals of the weld control as Z_{load}. When the weld control applies the voltage V_{load}(t) upon the load impedance, the resulting current is I_{load}(t).

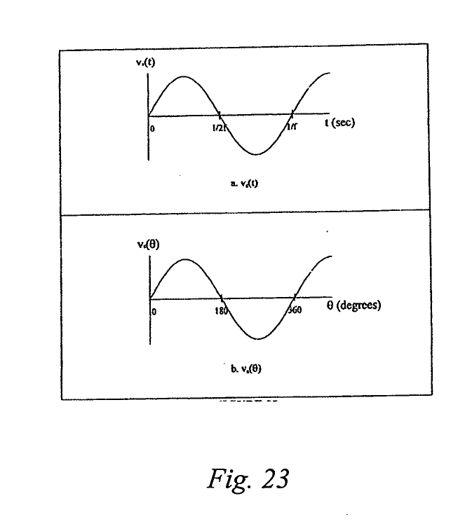

In what follows, the line impedance Zₗᵢₙₑ is assumed to be zero and the voltage source, Vₛ(t) is considered to be an ideal source of the form:
vₛ(t)=V sin(2πft) (82)
where V is the magnitude of line voltage and f is the line frequency (in Hz.) of the line voltage source. This sinusoidal waveform as a function of time is shown in FIG. 23 (top). Note that the zero crossings of this waveform occur at points for which the following holds:

$$t = \frac{n}{2 f} , \\ n = 0 , 1 , … \qquad ( 83 )$$

To remove the dependence upon frequency, timing in the resistance weld application is usually expressed as angles in degrees rather than time. In this analysis, the observation angle (corresponding to time) is designated as θ. FIG. 23 (bottom) shows the voltage waveform as a function of observation angle, with zero degrees referenced to a negative to positive zero crossing of the sinusoid. Note that in this case, the zero crossings of the sinusoid are at the angles:
θ=180*n, n=0, 1, . . . (84)

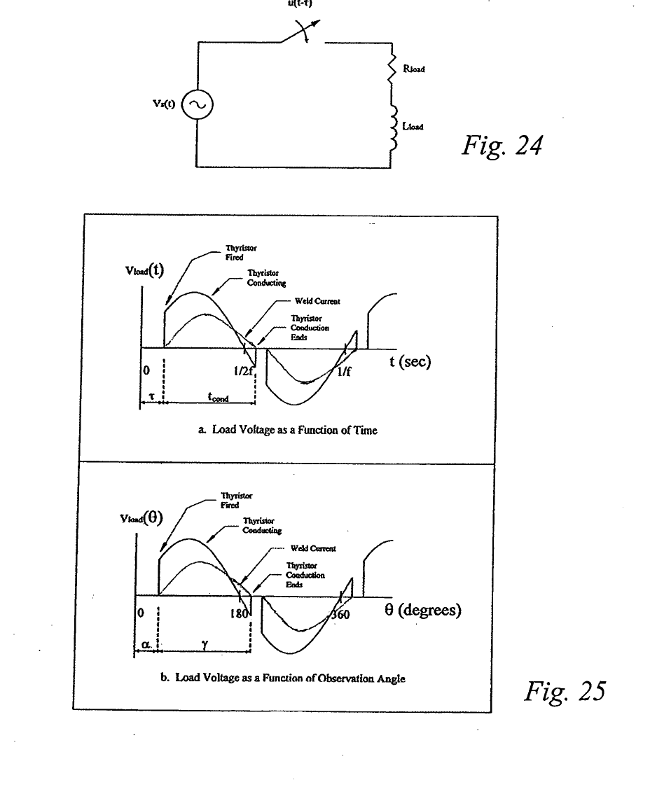

The thyristor switches are assumed to be ideal switches having no voltage drop. The load impedance, reflected to the primary side of the weld transformer, can be reasonably modeled as a lumped load resistance, R_{load} and a series load inductance, L_{load} as shown in FIG. 24.

The effect of firing the solid state thyristor welding contactor is to close the switch in FIG. 24 at a time t=τ (or at an angle α) with respect to the zero crossing of the voltage source as shown in FIG. 23. FIG. 25 shows the voltage waveform resulting from firing the thyristor. Once the switch is thrown and current begins to flow in the load, the switch remains closed until the current is again zero at a time t=τ+t_{cond} as shown in FIG. 25 (top), or at an angle θ=α+γ as shown in FIG. 25 (bottom). The actual value of t_{cond} or γ is dependent upon the firing point and the load circuit parameters and will be derived herein. Mathematically, the voltage applied to the load is of the form:
v_{load}(t)=V sin(2πft)*[u(t−τ)−u(τ−+t_{cond}))t] (85)
where u(t) is the unit step function.

The purpose of this analysis is to develop the closed form solution for the weld current resulting from firing the thyristor switch at a time τ with respect to the zero crossing of the source voltage vₛ(t) as given in (82) above and shown in FIG. 23. Additionally, the form of the current waveform will be developed that is a function of the angle of observation, θ as described in FIG. 23 (bottom). Another important quantity is the resulting conduction time, t_{cond}, or its equivalent conduction angle, γ, which is defined as the angle over which the thyristor conducts, or alternatively, the angle over which current flows as a result of firing the thyristor.

The following assumptions are made to simplify the analysis of weld current:

1. The voltage source, vₛ(t) is assumed ideal and hence “stiff”. There is no line impedance.

2. The frequency of the voltage source remains constant.

3. The thyristor switches are assumed to be ideal, having no voltage drop. Once triggered, a thyristor conducts until the current flowing through it is exactly zero.

4. The load impedance, comprising a load resistance and load inductance, reflected to the primary, is assumed constant throughout the weld. This results in a linear, time invariant system.

Under these assumptions, the closed form solution to the load current i_{load}(t) resulting from firing the thyristor at a time r with respect to the zero crossing of the sinusoidal input voltage is:

$$i ( t ) = ( \frac{V}{\sqrt{{R}_{load}^{2} + {( ω {L}_{load} )}^{2}}} ) [ \begin{matrix}sin ( ω t - ϕ ) - \\ {ⅇ}^{- \frac{ {R}_{ load}}{ {L}_{ load}} ( t - τ )} sin ( ωτ - ϕ )\end{matrix} ] u ( t - τ ) \qquad ( 86 )$$

where

V is the magnitude of the sinusoidal input voltage;

R is the resistance of the weld transformer, gun and tooling reflected to the primary of the weld transformer;

L is the inductance of the weld transformer, gun and tooling reflected to the primary of the weld transformer;

ω is the radian frequency of the line voltage source;

φ is the lag angle of the load impedance, defined by:

$$ϕ = {tan}^{- 1} \frac{ω L}{R} \qquad ( 87 )$$

and,

τ is the time at which the thyristor is fired relative to the zero crossing of the line voltage as shown in FIG. 25.

Expressed in terms of the observation angle θ, the load current i(θ) is:

$$i ( θ ) = ( \frac{V}{\vert {Z}_{load} \vert} ) [ sin ( θ - ϕ ) - {ⅇ}^{- \frac{( θ - α )}{tan ( ϕ )}} sin ( α - ϕ ) ] u ( θ - α ) \qquad ( 88 )$$

where

θ is the observation angle, measured from the negative to positive zero crossing of the sinusoidal voltage source;

φ is the lag angle of the load impedance as given by equation (87) above;

α is the firing angle, related to τ by
α=ωτ (89)
and,

|Z_{load}| is the magnitude of load impedance given by:
|Z_{load}|=\sqrt{R_{load}²+(ωL_{load})²} (90)

The conduction time, t_{cond} and analogous conduction angle, y are those values for which the following holds:

$$\begin{matrix}{t}_{cond} = {min}_{t : t > τ , i ( t ) = 0} \{ t - τ \} \\ and & ( 91 ) \\ γ = {min}_{θ > 0 , i ( θ ) = 0} ( θ - α ) & ( 92 )\end{matrix}$$

Assuming a stiff weld source allows for a simple presentation of the voltage waveform presented to the load. Referring to FIG. 22, when there is no line impedance present, the voltage V_{wc} observed by the weld control is identically that of the voltage source, Vₛ. If there is line impedance present, the line voltage observed by the weld control, V_{wc} will be reduced from that of Vₛ by the current flowing through the line impedance.

For purposes of analyzing the effect of the line impedance on the weld current, one could readily lump the line impedance and load impedance into a single entity. Assuming that the line impedance is also inductive in nature (ignoring the capacitance of the distribution system), equivalent resistance and inductance can be defined by:
R_{eq}=Rₗᵢₙₑ+R_{load} (93)
and
L_{eq}=Lₗᵢₙₑ+L_{load} (94)
If these values are substituted into the various equations above, the resulting current would be an accurate estimate of what is actually transpiring in the weld control.

A fixed radian line frequency X is required to make the assumption that the system is linear and time invariant. Without this assumption, the use of Laplace transform techniques would not be possible. Fortunately, this assumption is realized to a very high degree in application.

An ideal thyristor is assumed for simplicity. A model of a thyristor comprising a fixed voltage drop, or any linear model for the thyristor could also have been employed. If a model incorporating a fixed voltage drop is employed, it would be modeled as a DC voltage source. In a linear system model, the resulting weld current could be expressed as the superposition of the response to the sinusoid, as expressed in the equations above, and a DC voltage source impressed upon the system at the firing time.

A constant load impedance is required to permit analysis of the lumped parameter model as a linear, time invariant system. The inductance is primarily determined by the geometry of the tool and the work piece, and as such can change as the geometry of the tooling changes. An example of this is that the shunts and cables have a tendency to “jump” upon initiation of a weld. The resistance is usually pretty constant over the course of a half-cycle. It should be cautioned that during expulsion, a phenomenon in which molten metal is expelled from the weld tips and is usually observed as the shower of sparks emanating from the weld tips when too much heat is applied, the resistance can change very rapidly. In this case, the form of weld current will probably not follow the above equations well.

The basic form of the weld current can be derived as discussed below. Writing the loop equation for the circuit of FIG. 24 gives:

$${v}_{load} ( t ) = {R}_{load} i ( t ) + {L}_{load} \frac{ⅆ i ( t )}{ⅆ t} \qquad ( 95 )$$

Taking the Laplace Transform of equation (0-67) gives

$$\begin{matrix}{V}_{load} ( s ) = \frac{V {ⅇ}^{- s τ}}{j 2 ( {s}^{2} + {ω}^{2} )} [ s [ {ⅇ}^{jω τ} - {ⅇ}^{- j ω τ} ] + jω [ {ⅇ}^{jωτ} + {ⅇ}^{- jωτ} ] ] \\ or & ( 96 ) \\ {V}_{load} ( s ) = \frac{V {ⅇ}^{- s τ}}{( {s}^{2} + {ω}^{2} )} [ s sin ( ωτ ) + ω cos ( ωτ ) ] & ( 97 )\end{matrix}$$

From FIG. 24 one may write
V_{load}(s)=I(s)(R_{load}+sL_{load}) (98)
which when solved for I(s) results in

$$I ( s ) = \frac{{V}_{load} ( s )}{{R}_{load} + {sL}_{load}} = \frac{1}{{L}_{load}} \frac{{V}_{load} ( s )}{( s + \frac{{R}_{load}}{{L}_{load}} )} \qquad ( 99 )$$

To get the Laplace Transform of the load current, one multiplies equation (99) by equation (97) to obtain:

$$I ( s ) = \frac{V {ⅇ}^{- s τ}}{{L}_{load}} [ \frac{1}{( s + \frac{{R}_{load}}{{L}_{load}} ) ( {s}^{2} + {ω}^{2} )} ] [ s sin ( ωτ ) + ω cos ( ωτ ) ] \qquad ( 100 )$$

which can be written in the form:

$$I ( s ) = \frac{V {ⅇ}^{- s τ}}{{L}_{load}} F ( s ) [ s sin ( ωτ ) + ω cos ( ωτ ) ] \qquad ( 101 )$$

with F(s) given by:

$$F ( s ) = [ \frac{1}{( s + \frac{{R}_{load}}{{L}_{load}} ) ( {s}^{2} + {ω}^{2} )} ] \qquad ( 102 )$$

Now, note the following properties of the Laplace Transform:

1. The term e^{-sτ} implies a time delay, that is:
L{f(t−τ)}=e^{-sτ}L{f(t)} (103)

2. The Laplace transform of the derivative of a function is of the form:

$$ℒ \{ \frac{ⅆ f ( t )}{ⅆ t} \} = s ℒ \{ f ( t ) \} - f ( 0 ) \qquad ( 104 )$$

Examining equation (101) in the light of (103) and (104), if the inverse Laplace transform of F(s) is f(t), the load current i(t) can be written as:

$$i ( t ) = \frac{V}{L} [ sin ( ωτ ) \frac{ⅆ f ( t - τ )}{ⅆ t} + ω cos ( ωτ ) f ( t - τ ) ] \qquad ( 105 )$$

Thus, if f(t) can be found from (102), equation (105) shows how to derive the weld current. F(s) can be expanded into partial fraction representation of the form:

$$\frac{1}{( s + \frac{{R}_{load}}{{L}_{load}} ) ( {s}^{2} + {ω}^{2} )} = \frac{a}{( s + \frac{{R}_{load}}{{L}_{load}} )} + \frac{bs + c}{( {s}^{2} + {ω}^{2} )} \qquad ( 106 )$$

Cross-multiplying and gathering terms in (106) results in:

$$( a + b ) {s}^{2} + ( \frac{{R}_{load}}{{L}_{load}} b + c ) s + ( {ω}^{2} a + \frac{{R}_{load}}{{L}_{load}} c - 1 ) = 0 \qquad ( 107 )$$

Equation (107) is a polynomial in ‘s’. To satisfy (107) over all values of s, the coefficients of each term of the polynomial must be zero. This gives the following relations between a, b and c:
a+b=0 (108)

$$\begin{matrix}( \frac{{R}_{load}}{{L}_{load}} b + c - 1 ) = 0 \\ and & ( 109 ) \\ ( {ω}^{2} a + \frac{{R}_{load}}{{L}_{load}} c ) = 0 & ( 110 )\end{matrix}$$

Solving for ‘a’ in (106) gives:

$$a = {lim}_{s -> \frac{- {R}_{load}}{{L}_{load}}} ( \frac{1}{{s}^{2} + {ω}^{2}} ) = \frac{1}{{ω}^{2} + {( \frac{{R}_{load}}{{L}_{load}} )}^{2}} \qquad ( 111 )$$

From (108), ‘b’ is found to be:

$$b = - a = - \frac{1}{{ω}^{2} + {( \frac{{R}_{load}}{{L}_{load}} )}^{2}} \qquad ( 112 )$$

Solving (109) for ‘c’ yields

$$c = \frac{{L}_{load}}{{R}_{load}} ( 1 - a {ω}^{2} ) \qquad ( 113 )$$

Substituting (111) and simplifying results in

$$c = \frac{\frac{{R}_{load}}{{L}_{load}}}{{ω}^{2} + {( \frac{{R}_{load}}{{L}_{load}} )}^{2}} \qquad ( 114 )$$

Substituting (111), (112) and (114) back into (106) gives:

$$F ( s ) = \frac{1}{( s + \frac{{R}_{load}}{{L}_{load}} ) ( {s}^{2} + {ω}^{2} )} = ( \frac{1}{{ω}^{2} + {( \frac{{R}_{load}}{{L}_{load}} )}^{2}} ) ( \frac{1}{( s + \frac{{R}_{load}}{{L}_{load}} )} + \frac{- s}{( {s}^{2} + {ω}^{2} )} + \frac{\frac{{R}_{load}}{{L}_{load}}}{( {s}^{2} + {ω}^{2} )} ) \qquad ( 115 )$$

Taking the inverse Laplace transform of (115) gives:

$$f ( t ) = ( \frac{1}{{ω}^{2} + {( \frac{{R}_{load}}{{L}_{load}} )}^{2}} ) ( {ⅇ}^{- \frac{{R}_{load}}{{L}_{load}} t} - cos ( ω t ) + \frac{{R}_{load}}{ω {L}_{load}} sin ( ω t ) ) u ( t ) \qquad ( 116 )$$

Taking the derivative of (116) gives

$$\frac{ⅆ f ( t )}{ⅆ t} = ( \frac{1}{{ω}^{2} + {( \frac{{R}_{load}}{{L}_{load}} )}^{2}} ) ( - \frac{{R}_{load}}{{L}_{load}} {ⅇ}^{- \frac{{R}_{load}}{{L}_{load}} t} + ω sin ( ω t ) + \frac{{R}_{load}}{{L}_{load}} cos ( ω t ) ) u ( t ) \qquad ( 117 )$$

Substituting (116) and (117) into (105) gives:

$$i ( t ) = \frac{V}{{L}_{load}} ( \frac{1}{{ω}^{2} + {( \frac{{R}_{load}}{{L}_{load}} )}^{2}} ) [ \begin{matrix}{ⅇ}^{- \frac{{R}_{load}}{{L}_{load}} ( t - τ )} ( ω cos ( ω τ ) - \frac{{R}_{load}}{{L}_{load}} sin ( ω t ) ) + \\ \frac{{R}_{load}}{{L}_{load}} ( sin ( ωτ ) cos ( ω t - ωτ ) + \\ cos ( ωτ ) sin ( ω t - ωτ ) ) - \\ ω ( sin ( ω τ ) sin ( ω t - ωτ ) - \\ cos ( ωτ ) cos ( ω t - ωτ ) )\end{matrix} ] \qquad ( 118 )$$

Rearranging terms gives:

$$i ( t ) = \frac{V}{{L}_{load}} ( \frac{1}{{ω}^{2} + {( \frac{{R}_{load}}{{L}_{load}} )}^{2}} ) [ \begin{matrix}{ⅇ}^{- \frac{{R}_{load}}{{L}_{load}} ( t - τ )} ( ω cos ( ω t ) - \frac{{R}_{load}}{{L}_{load}} sin ( ω t ) ) + \\ \frac{{R}_{load}}{{L}_{load}} ( sin ( ωτ ) cos ( ω t - ω τ ) + \\ cos ( ωτ ) sin ( ω t - ωτ ) ) - \\ ω ( sin ( ωτ ) sin ( ω t - ωτ ) - \\ cos ( ωτ ) cos ( ω t - ωτ ) )\end{matrix} ] \qquad ( 119 )$$

Two trigonometric identities that can be used to simplify (119) are:
sin(A±B)=sin(A)cos(B)±cos(A)sin(B) (120)
and
cos(A±B)=cos(A)cos(B)∓sin(A) sin(B) (121)

Applying these identities to (119) results in

$$i ( t ) = \frac{V}{{L}_{load}} ( \frac{1}{{ω}^{2} + {( \frac{{R}_{load}}{{L}_{load}} )}^{2}} ) [ \begin{matrix}{ⅇ}^{{}_{- \frac{{R}_{load}}{{L}_{load}} ( t - τ )}} ( ω cos ( ωτ ) - \frac{{R}_{load}}{{L}_{load}} sin ( ωτ ) ) + \\ \frac{{R}_{load}}{{L}_{load}} ( sin ( ω t ) ) - ω ( cos ( ω t ) )\end{matrix} ] u ( t - τ ) \qquad ( 122 )$$

A fundamental concept of AC circuit analysis is that of the lag angle of an R-L circuit, denoted by φ and defined as:

$$ϕ = {tan}^{- 1} ( \frac{ω L}{R} ) \qquad ( 123 )$$

from which the following relations can be written:

$$\begin{matrix}sin ( ϕ ) = \frac{ω}{\sqrt{{R}^{2} + {( ω L )}^{2}}} \\ and & ( 124 ) \\ cos ( ϕ ) = \frac{R}{\sqrt{{R}^{2} + {( ω L )}^{2}}} & ( 125 )\end{matrix}$$

To facilitate the use of these relations, first multiply through (122) by the quantity L/L=1 and rearrange the terms to give:

$$i ( t ) = ( \frac{V}{\sqrt{\begin{matrix}{R}_{load}^{2} + \\ {( ω {L}_{load} )}^{2}\end{matrix}}} ) [ \begin{matrix}{ⅇ}^{- \frac{{R}_{load}}{{L}_{load}} ( t - τ )} ( \begin{matrix}\frac{ω {L}_{load}}{\sqrt{{R}_{load}^{2} + {( ω {L}_{load} )}^{2}}} cos ( ωτ ) - \\ \frac{R}{\sqrt{{{R}^{2 +} ( ω L )}^{2}}} sin ( ωτ )\end{matrix} ) + \\ \begin{matrix}\frac{{R}_{load}}{\sqrt{{R}_{load}^{2} + {( ω {L}_{load} )}^{2}}} sin ( ω t ) - \\ \frac{ω {L}_{load}}{\sqrt{{R}_{load}^{2} + {( ω {L}_{load} )}^{2}}} cos ( ω t )\end{matrix}\end{matrix} ] u ( t - τ ) \qquad ( 126 )$$

Now, applying (124) and (125) yields

$$i ( t ) = ( \frac{V}{\sqrt{\begin{matrix}{R}_{load}^{2} + \\ {( ω {L}_{load} )}^{2}\end{matrix}}} ) [ \begin{matrix}{ⅇ}^{- \frac{{R}_{load}}{{L}_{load}} ( t - τ )} ( sin ( ϕ ) cos ( ωτ ) - cos ( ϕ ) sin ( ωτ ) ) + \\ cos ( ϕ ) sin ( ω t ) - sin ( ϕ ) cos ( ω t )\end{matrix} ] u ( t - τ ) \qquad ( 127 )$$

Applying (120) to (127) gives

$$i ( t ) = ( \frac{V}{\sqrt{{R}_{load}^{2} + {( ω {L}_{load} )}^{2}}} ) [ \begin{matrix}sin ( ω t - ϕ ) - \\ {ⅇ}^{- \frac{{R}_{load}}{{L}_{load}} ( t - τ )} sin ( ωτ - ϕ )\end{matrix} ] u ( t - τ ) \qquad ( 128 )$$

Equation (128) is the normal form for the equation of weld current as a function of time for parametric values of firing time, τ, with respect to the zero crossing of line voltage, the radian line frequency ω and the equivalent load resistance R and load inductance L reflected to the primary of the weld transformer.

The point at which the Thyristor switch is fired is normally expressed in terms of a firing angle, α, rather than a firing time. The firing angle, α, is related to the firing time, τ, and the radian line frequency ω by:
α=ωτ (129)
Similarly, we can define the observation angle, θ, by
θ=ωτ (130)

With these two quantities defined, one may rewrite the exponential in (128) as

$${ⅇ}^{- \frac{{R}_{load}}{{L}_{load}} ( t - τ )} = {ⅇ}^{- \frac{{R}_{load}}{ω {L}_{load}} ω ( t - τ )} \qquad ( 131 )$$

Applying (123), (130) and (129) to (131) gives

$${ⅇ}^{- \frac{{R}_{load}}{{L}_{load}} ( t - τ )} = {ⅇ}^{- \frac{( θ - α )}{tan ( ϕ )}} \qquad ( 132 )$$

Also, the magnitude of the AC load impedance of the R-L circuit is recognized as:
|Z_{load}|=\sqrt{R_{load}²+(ωL_{load})²} (133)

Substituting (133), (132), (129) and (130) into (128) gives:

$$i ( θ ) = ( \frac{V}{\vert {Z}_{load} \vert} ) [ \begin{matrix}sin ( θ - ϕ ) - \\ {ⅇ}^{- \frac{( θ - α )}{tan ( ϕ )}} sin ( α - ϕ )\end{matrix} ] u ( θ - α ) \qquad ( 134 )$$

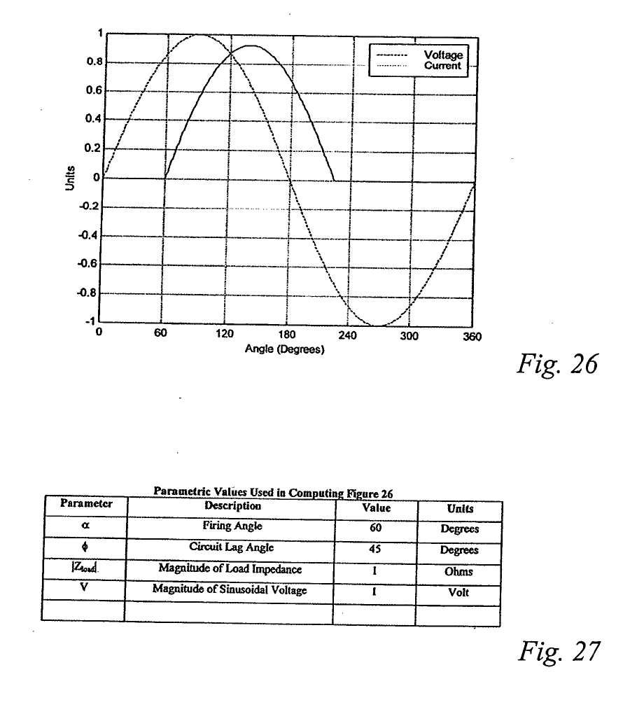

as an expression of weld current in terms of the firing angle, α, circuit lag angle, φ and observation angle θ. FIG. 26 is a plot of the current waveform resulting from applying the parametric values shown in FIG. 27 to Equation (134).

Once the thyristor fires and current begins conducting, the thyristor continues to conduct current until the current naturally extinguishes itself at a zero crossing. Using equation (128), the time at which the thyristor switches off satisfies:

$${t}_{cond} = {min}_{t \text{:} t > τ , i ( t ) = 0} \{ t - τ \} \qquad ( 135 )$$

where i(t) is given by (128) above. Equation (135) is the mathematically rigorous statement that the conduction time is the interval between the firing of the thyristor (at t=τ), and the first time the weld current again passes through zero. There is no closed form solution for t_{cond}, but equation (128) can be solved iteratively to a high degree of precision. Similarly, the conduction angle, γ, is that angle that satisfies:

$$γ = {min}_{θ > 0 , i ( θ ) = 0} ( θ - α ) \qquad ( 136 )$$

A closed form solution for the weld current can be found assuming a linear lumped parameter model of the weld circuit. While the analysis presented herein makes a great many assumptions, some of which may be considered suspect in an actual weld application, the results presented have been generally accepted as “the solution” for weld current and have been referenced repeatedly in the literature. A more accurate modeling of the system can be readily achieved incorporating a model for the source impedance presented by the weld voltage source, and effects of the thyristor can also be readily explored assuming linear models for each.

While the specific embodiments have been illustrated and described, numerous modifications come to mind without significantly departing from the spirit of the invention, and the scope of protection is only limited by the scope of the accompanying Claims.

What is claimed is:

1. A method for estimating a driving point voltage of a resistance weld system comprising the steps of:
periodically sampling a supplied voltage and a supplied current of a system to obtain sets of a sampled voltage value and a sampled current value;
taking a first set of a sampled voltage value and a sampled current value;
taking a second set of a sampled voltage value and a sampled current value;
taking a third set of a sampled voltage value and a sampled current value;
computing a current difference value for each of the first set, second set and third set; and,
creating an estimated line resistance and an estimated line reactance of the system based on the first set of a sampled voltage value, a sampled current value and computed current difference value, the second set of a sampled voltage value, a sampled current value and computed current difference value, and the third set of a sampled voltage value, a sampled current value and computed current difference value.

2. The method of claim 1 wherein the step of taking a first set of a sampled voltage value and a sampled current value comprises:
determining if the current is one of flowing and not flowing; and,
sampling the voltage when the current is not flowing.

3. The method of claim 1 further comprising the steps of:
creating a volt time area of the sampled voltage;
creating a current time area of the sample current; and,
creating a current difference time area of the sampled current,
using the volt time area of the sampled voltage, the current time area of the sampled current, the current difference time area of the sampled current, the estimated line resistance and the estimated line reactance to create an estimated driving point voltage time area.

4. The method of claim 3 further comprising the step of:
using the estimated driving point voltage time area to drive the firing of a thyristor of a resistance weld device.

5. The method of claim 1 wherein the steps of creating a volt time area of the sampled voltage, creating a current time area of the sampled current, and creating a current difference time area of the sampled current is done on a quadrant by quadrant basis.

6. The method of claim 5 wherein the step of periodically sampling a supplied voltage and supplied current of a system comprises sampling the supplied voltage and current a set number of times for each quadrant.

7. The method of claim 3 further comprising the step of:
using the estimated driving point voltage time area to compute a phase error between the supplied voltage and an internal phase reference.

8. The method of claim 7 further comprising the step of:
using the computed phase error in the step of
using the volt time area of the sampled voltage, the current time area of the sampled current, the current difference time area of the sampled current, the estimated line resistance and the estimated line reactance to create an estimated driving point voltage time area.

9. A system for estimating a driving point voltage of a resistance weld control comprising:
circuitry for periodically sampling a supplied voltage and a supplied current of a system to obtain a plurality of sets of a sampled voltage value and a sampled current value;
circuitry for creating a volt time area of the sampled voltage;
circuitry for creating a current time area of the sampled current;
circuitry for creating a current difference time area of the sampled current;
circuitry for determining if current is one of flowing and not flowing;
circuitry for taking a first set of a sampled voltage value and a sampled current value when the current is not flowing;
circuitry for taking a second set of a sampled voltage value and a sampled current value when the current is flowing; and,
circuitry for creating an estimated line resistance and an estimated line reactance of the system based on the first set of a sampled voltage value and a sampled current value and the second set of a sampled voltage value and a sampled current value.

10. The system of claim 9 further comprising:
circuitry for using the volt time area of the sampled voltage, the current time area of the sampled current, the current difference time area of the sampled current, the estimated line resistance and the estimated line reactance to create an estimated driving point voltage time area.

11. The system of claim 10 further comprising:
circuitry for using the estimated driving point voltage time area to drive the firing of a thyristor of a resistance weld device.

12. The system of claim 10 wherein the system comprises a digital signal processor.

13. The system of claim 9 wherein the circuitry for creating a volt time area of the sampled voltage, creating a current time area of the sampled current, and creating a current difference time area of the sampled current comprises circuitry for performing creating a volt time area of the sampled voltage, creating a current time area of the sampled current, and creating a current difference time area of the sampled current on a quadrant by quadrant basis.

14. The system of claim 12 wherein the circuitry for periodically sampling a supplied voltage and a supplied current of a system comprises circuitry for sampling the supplied voltage and supplied current a set number of times for each quadrant.

15. A method for estimating a driving point voltage for timing the firing elements of a resistance weld device comprising the steps of:
measuring a supplied voltage and a supplied current of a power distribution system at a plurality of predetermined intervals;
estimating a line resistance and a line reactance based on measured values of the supplied voltage and the supplied current;
estimating the driving point voltage based on the measured values of supplied voltage and the supplied current, and on the estimated line resistance and line reactance.

16. The method of claim 15 further comprising the steps of:
calculating a voltage time area of the supplied voltage from the measured values of the supplied voltage;
calculating a current time area of the supplied current from the measured values of the supplied current; and,
calculating a current difference time area of the supplied current from the measured values of the supplied current, wherein the voltage time area, the current time area and the current difference time area are used for estimating the driving point voltage.

17. The method of claim 15 wherein the step of estimating a line resistance and a line reactance comprises the steps of:
measuring a first set of a sampled voltage value and a sampled current value when the current is not flowing;
measuring a second set of a sampled voltage value and a sampled current value when the current is flowing; and,
creating an estimated line resistance and an estimated line reactance of the system based on the first set of a sampled voltage value and a sampled current value and the second set of a sampled voltage value and a sampled current value.

18. The method of claim 17 further comprising the step of:
determining whether the current is one of flowing and not flowing for each of the plurality of predetermined intervals.

19. The method of claim 18 further comprising the step of:
providing a firing signal to a thyristor of a resistance weld device based on the estimated driving point voltage.

20. The method of claim 15 further comprising the step of:
estimating a phase error between the supplied voltage and the estimated driving point voltage.

21. The method of claim 20 further comprising the step of:
using the estimated phase error as feedback for further calculations of the estimated driving point voltage.
